(19) United States
(12) Patent Application Publication
(10) Pub. No.: US 2024/0421028 A1
(43) Pub. Date: Dec. 19, 2024

(54) COOLER AND SEMICONDUCTOR MODULE

(71) Applicant: ROHM CO., LTD., Kyoto-shi (JP)

(72) Inventor: Masashi HAYASHIGUCHI, Kyoto-shi (JP)

(21) Appl. No.: 18/823,279

(22) Filed: Sep. 3, 2024

Related U.S. Application Data
(63) Continuation of application No. PCT/JP2023/008826, filed on Mar. 8, 2023.

(30) Foreign Application Priority Data
Mar. 22, 2022 (JP) 2022-045601

(51) Int. Cl. H01L 23/367; H01L 23/40

(52) U.S. Cl. CPC H01L 23/3675; H01L 23/4006; H01L 2023/405

(57) ABSTRACT

A cooler includes a housing and a heat dissipator. The housing includes a recess that opens on a first side in a first direction and a bottom part located on a second side in the first direction and defining a part of the recess. The heat dissipator is attached to the bottom part and at least partially housed in the recess. The bottom part includes a flexible portion that deforms elastically. When a load toward the second side in the first direction is applied to the heat dissipator, an elastic force toward the first side in the first direction, which is generated from the flexible portion, acts on the heat dissipator. A semiconductor module includes a cooler, a semiconductor device disposed on the cooler, and a mounting member that holds the semiconductor device on the cooler.

### TECHNICAL FIELD

The present disclosure relates to a cooler. The present disclosure also relates to a semiconductor module including a cooler and a semiconductor device disposed on the cooler.

### BACKGROUND ART

WO-A1-2017/094370 discloses an example of a cooler with a semiconductor device disposed on it. The cooler includes a housing with a hollow region, and a radiator. The housing has an opening leading to the hollow region. The radiator is attached to the housing to close the opening. The semiconductor device is bonded to a portion of the radiator that protrudes outward from the hollow region. When the hollow region is filled with cooling water, the cooling water contacts the radiator. This allows cooling of the semiconductor device.

In the cooler disclosed in WO-A1-2017/094370, the cooling of the semiconductor device is performed indirectly via the radiator. Moreover, since a gap exists between the radiator and the housing in the hollow region, the cooling water tends to concentrate in the gap. This may result in insufficient cooling of the radiator and the semiconductor device by the cooling water.

### BRIEF DESCRIPTION OF THE DRAWINGS

FIG. 1 is a plan view of a cooler according to a first embodiment of the present disclosure.

FIG. 2 is a front view of the cooler shown in FIG. 1.

FIG. 3 is a left side view of the cooler shown in FIG. 1.

FIG. 4 is a partial enlarged view FIG. 1.

FIG. 5 is a sectional view taken along line V-V in FIG. 4.

FIG. 6 is a sectional view taken along line VI-VI in FIG. 4.

FIG. 7 is a perspective view of one of a plurality of semiconductor devices constituting a semiconductor module shown in FIG. 20.

FIG. 8 is a plan view of the semiconductor device shown in FIG. 7.

FIG. 9 is a plan view corresponding to FIG. 8, in which the sealing resin is transparent.

FIG. 10 is a partial enlarged view FIG. 9.

FIG. 11 is a plan view corresponding to FIG. 8, in which the first conductive member is transparent while illustration of the sealing resin and the second conductive member is omitted.

FIG. 12 is a right side view of the semiconductor device shown in FIG. 7.

FIG. 13 is a bottom view of the semiconductor device shown in FIG. 7.

FIG. 14 is a sectional view taken along line XIV-XIV in FIG. 9.

FIG. 15 is a sectional view taken along line XV-XV in FIG. 9.

FIG. 16 is a partial enlarged view of the first element and the nearby portion shown in FIG. 15.

FIG. 17 is a partial enlarged view of the second element and the nearby portion shown in FIG. 15.

FIG. 18 is a sectional view taken along line XVIII-XVIII in FIG. 9.

FIG. 19 is a sectional view taken along line XIX-XIX in FIG. 9.

FIG. 20 is a plan view of a semiconductor module according to a first embodiment of the present disclosure.

FIG. 21 is a front view of the semiconductor module shown in FIG. 20.

FIG. 22 is an enlarged sectional view of a part of the semiconductor module shown in FIG. 20.

FIG. 23 is an enlarged plan view of a part of a cooler according to a second embodiment of the present disclosure.

FIG. 24 is a sectional view taken along line XXIV-XXIV in FIG. 23.

FIG. 25 is a sectional view taken along line XXV-XXV in FIG. 23.

FIG. 26 is an enlarged sectional view of a part of a semiconductor module according to a second embodiment of the present disclosure.

FIG. 27 is an enlarged plan view of a part of a cooler according to a third embodiment of the present disclosure.

FIG. 28 is a sectional view taken along line XXVIII-XXVIII in FIG. 27.

FIG. 29 is a sectional view taken along line XXIX-XXIX in FIG. 27.

FIG. 30 is an enlarged sectional view of a part of the semiconductor module according to the third embodiment of the present disclosure.

FIG. 31 is an enlarged plan view of a part of a cooler according to a fourth embodiment of the present disclosure.

FIG. 32 is a sectional view taken along line XXXII-XXXII in FIG. 31.

FIG. 33 is a sectional view taken along line XXXIII-XXXIII in FIG. 31.

FIG. 34 is an enlarged sectional view of a part of a semiconductor module according to a fourth embodiment of the present disclosure.

FIG. 35 is an enlarged plan view of a part of the cooler according to the fourth embodiment of the present disclosure.

### DETAILED DESCRIPTION OF EMBODIMENTS

Modes for carrying out the present disclosure are described below with reference to the accompanying drawings.

### First Embodiment (Cooler)

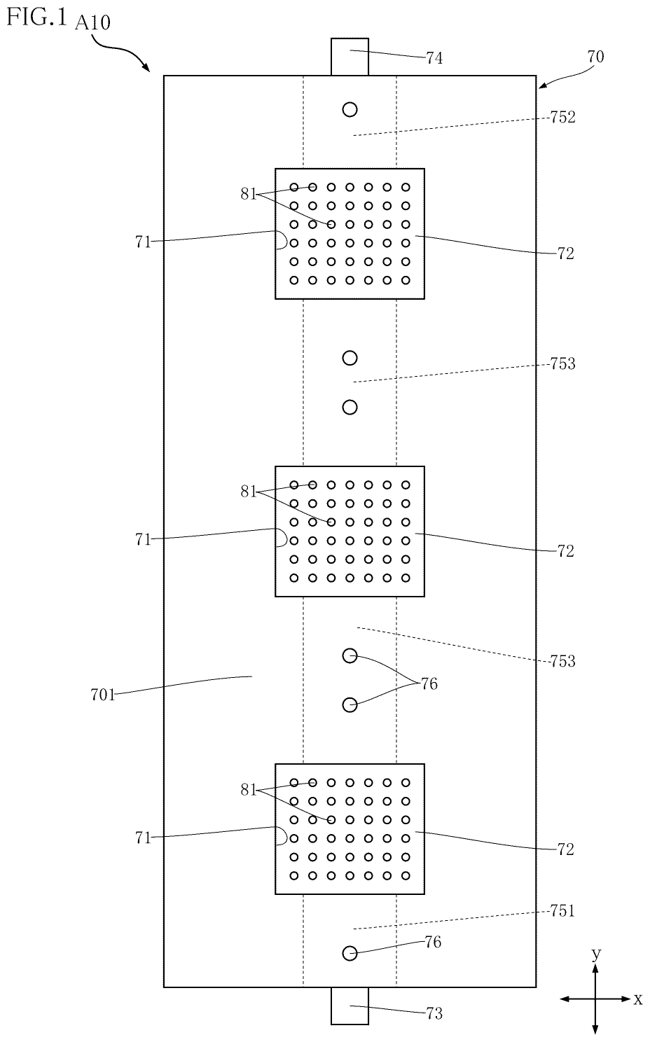

A cooler A10 according to a first embodiment of the present disclosure will be described based on FIGS. 1 to 6. The cooler A10 is used to cool a plurality of semiconductor devices B that constitutes a semiconductor module C10, described later. The cooler A10 includes a housing 70 and heat dissipators 81.

In the description of the cooler A10, the direction which is normal to the obverse surface 701 of the housing 70, described later, is defined as the “first direction z” for the convenience. A direction orthogonal to the first direction z is defined as the “second direction x”. The direction orthogonal to the first direction z and the second direction x is defined as the “third direction y”. The definition of the first direction z, the second direction x, and the third direction y also applies to the semiconductor device B and the semiconductor module C10 described later.

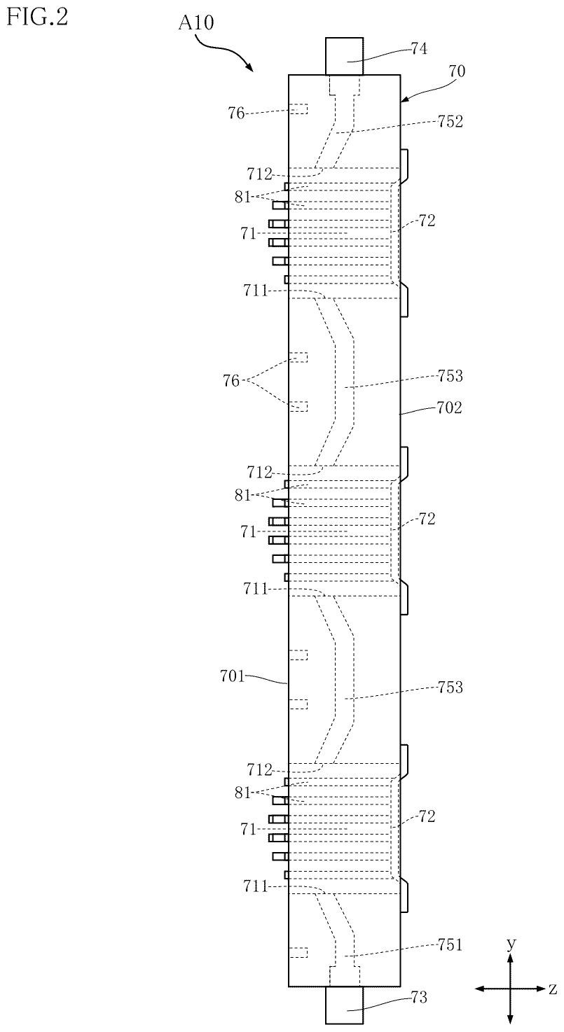

As shown in FIGS. 1 and 2, the housing 70 forms the main part of the cooler A10. In the cooler A10, the housing 70 is molded in one piece except bottom parts 72. The integrally molded portion of the housing 70 is made of, for example, a material containing aluminum.

As shown in FIGS. 1 to 6, the housing 70 has a plurality of recesses 71 and a plurality of bottom parts 72. The recesses 71 are open on a first side in the first direction z. The recesses 71 are arranged along the third direction y. The bottom parts 72 are located on a second side in the first direction z, each defining a part of a recess 71.

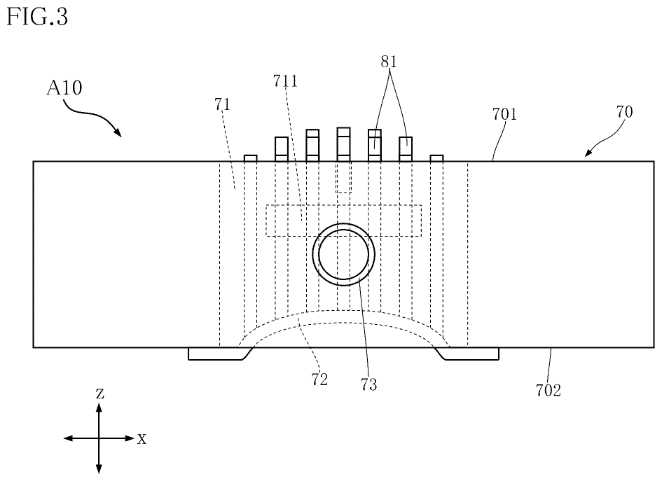

As shown in FIGS. 3, 5 and 6, the housing 70 has an obverse surface 701 and a reverse surface 702. The obverse surface 701 faces the side on which the heat dissipator 81 is located with respect to the bottom part 72 in the first direction z. The obverse surface 701 surrounds the recess 71. The recess 71 is recessed from the obverse surface 701 in the first direction z. The reverse surface 702 faces away from the obverse surface 701 in the first direction z.

Each of the bottom parts 72 includes a flexible portion 721 that deforms elastically. In the cooler A10, the flexible portion 721 is molded in one piece, and the entirety of the bottom part 72 is the flexible portion 721. The flexible portion 721 is made of a material containing, for example, natural rubber. Alternatively, the material of the flexible portion 721 may be a metal. In the cooler A10, the bottom part 72 is bonded to the reverse surface 702 of the housing 70 by vulcanization, for example. Alternatively, the bottom part 72 may be integral with the housing 70. The configuration of the bottom part 72 is not limited as long as it includes a flexible portion 721 that deforms elastically.

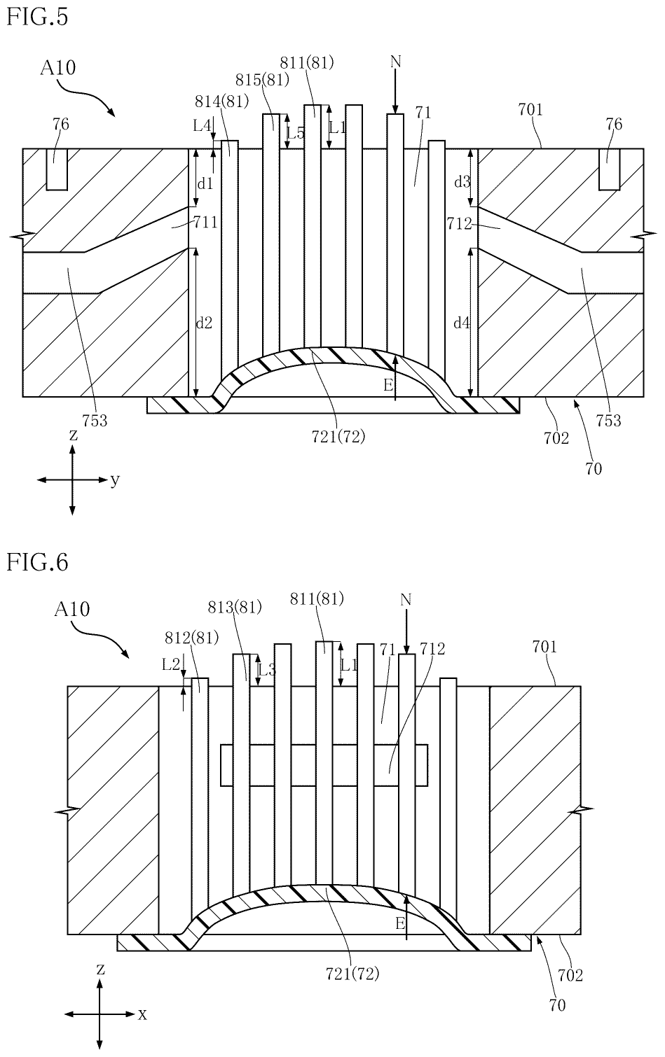

As shown in FIGS. 5 and 6, the heat dissipator 81 is attached to the bottom part 72. At least a part of the heat dissipator 81 is housed in the recess 71. The thermal conductivity of the heat dissipator 81 is higher than that of the housing 70.

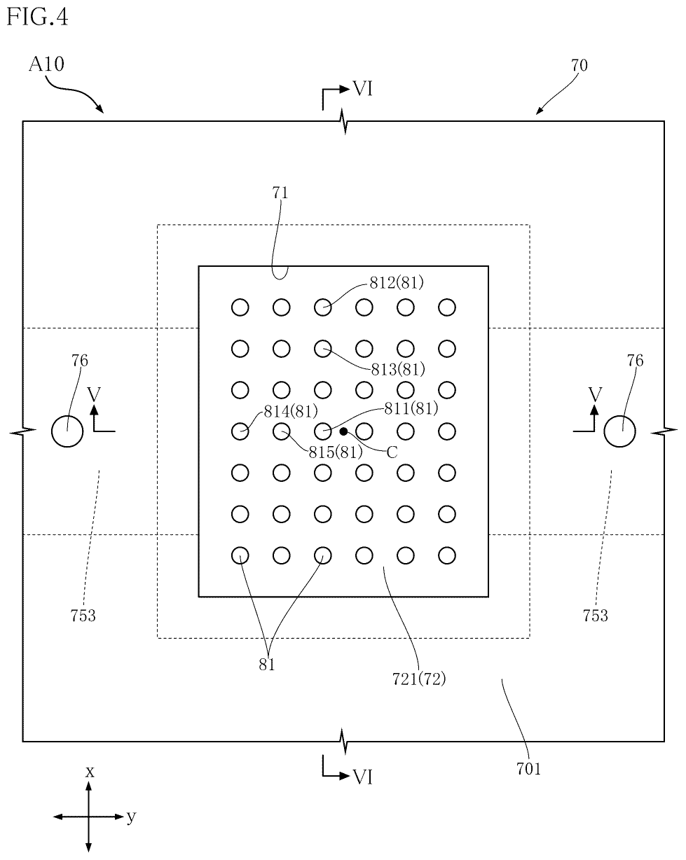

As shown in FIGS. 4 to 6, the heat dissipator 81 includes a first member 811, a second member 812, a third member 813, a fourth member 814, and a fifth member 815. The first member 811, the second member 812, the third member 813, the fourth member 814, and the fifth member 815 each have a rod shape extending in the first direction z and supported on the flexible portion 721 of the bottom part 72. The dimensions in the first direction z of the first member 811, the second member 812, the third member 813, the fourth member 814, and the fifth member 815 are equal to each other. As shown in FIG. 4, the first member 811, the second member 812, the third member 813, the fourth member 814, and the fifth member 815 are surrounded by the obverse surface 701 of the housing 70 as viewed in the first direction z. As shown in FIGS. 5 and 6, each of the first member 811, the second member 812, the third member 813, the fourth member 814, and the fifth member 815 includes a part that protrudes outward from the obverse surface 701 when the flexible portion 721 is in its natural state. The natural state of the flexible portion 721 refers to the state in which only the weight of the heat dissipator 81 is acting on the flexible portion.

As shown in FIGS. 4 and 6, the first member 811 and the second member 812 are spaced apart from each other in the second direction x. The first member 811 is closest to the center C of the recess 71 as viewed in the first direction z. The center C coincides with the centroid of the plane figure defined by the periphery of the recess 71 as viewed in the first direction z. The second member 812 is closest to the obverse surface 701 of the housing 70. The third member 813 is located between the first member 811 and the second member 812 in the second direction x.

As shown in FIG. 6, when the flexible portion 721 of the bottom part 72 is in its natural state, the protruding amount L1 by which the first member 811 protrudes outward from the obverse surface 701 of the housing 70 is greater than the protruding amount L2 by which the second member 812 protrudes outward from the obverse surface 701. Also, the protruding amount L3 by which the third member 813 protrudes outward from the obverse surface 701 is smaller than the protruding amount L1 and greater than the protruding amount L2.

As shown in FIGS. 4 and 5, the first member 811 and the fourth member 814 are spaced apart from each other in the third direction y. The fourth member 814 is closest to the obverse surface 701 of the housing 70. The fifth member 815 is located between the first member 811 and the fourth member 814 in the third direction y.

As shown in FIG. 5, when the flexible portion 721 of the bottom part 72 is in its natural state, the protruding amount L1 by which the first member 811 protrudes outward from the obverse surface 701 of the housing 70 is greater than the protruding amount L4 by which the fourth member 814 protrudes outward from the obverse surface 701. Also, the protruding amount L5 by which the fifth member 815 protrudes outward from the obverse surface 701 is smaller than the protruding amount L1 and greater than the protruding amount L4.

As shown in FIGS. 5 and 6, the bottom part 72 bulges toward the side on which the heat dissipator 81 is located in the first direction z. In the bottom part 72, the center C shown in FIG. 4 is farthest from the reverse surface 702 of the housing 70 in the first direction z.

As shown in FIGS. 5 and 6, when a load N toward the second side in the first direction z (the side on which the bottom part 72 is located with respect to the heat dissipator 81 in the first direction z) is applied, the elastic force E toward the first side in the first direction z (the side on which the heat dissipator 81 is located with respect to the bottom part 72 in the first direction z), which is generated from the flexible portion 721 of the bottom part 72, acts on the heat dissipator 81. The elastic force E is generated by the elastic deformation of the flexible portion 721 due to the load N transmitted from the heat dissipator 81 to the bottom part 72. The elastic force E is the reaction of the load N.

As shown in FIG. 2, each of the recesses 71 is provided with an inlet 711 and an outlet 712. The inlet 711 and the outlet 712 are located opposite to each other across the recess 71 in the third direction y. The inlet 711 and the outlet 712 are located between the obverse surface 701 and the reverse surface 702 of the housing 70 in the first direction z. The inlet 711 and the outlet 712 are connected to the recess 71.

As shown in FIGS. 3 and 6, as viewed in the third direction y, the first member 811 of the heat dissipator 81 overlaps with the inlet 711 and the outlet 712. As shown in FIG. 5, the distance d1 between the inlet 711 and the obverse surface 701 of the housing 70 in the first direction z is shorter than the distance d2 between the inlet 711 and the reverse surface 702 of the housing 70 in the first direction z. The distance d3 d1 between the outlet 712 and the obverse surface 701 in the first direction z is shorter than the distance d4 between the outlet 712 and the reverse surface 702 in the first direction z.

As shown in FIGS. 1 and 2, the housing 70 has an inlet part 73, an outlet part 74, a first flow path 751, a second flow path 752, and two intermediate flow paths 753. The inlet part 73 and the outlet part 74 are located opposite to each other across the obverse surface 701 of the housing 70 in the third direction y. The first flow path 751 connects the inlet part 73 and the inlet 711 of one of the recesses 71 that is closest to the inlet part 73. The second flow path 752 connects the outlet part 74 and the outlet 712 of one of the recesses 71 that is closest to the outlet part 74. Each of the two intermediate flow paths 753 connects the outlet 712 of one of two recesses 71 adjacent to each other in the third direction y and the inlet 711 of the other recess 71. The cooler A10 can allow cooling water to flow down from the inlet part 73 through the first flow path 751 and two intermediate flow paths 753 while filling the recesses 71 with the cooling water. The cooling water filling the recesses 71 can be discharged to the outside through the second flow path 752 and the outlet part 74. The cooing water discharged to the outside can be cooled again and allowed to flow down again from the inlet part 73, thereby circulating in the cooler A10 and the outside.

### Semiconductor Device B:

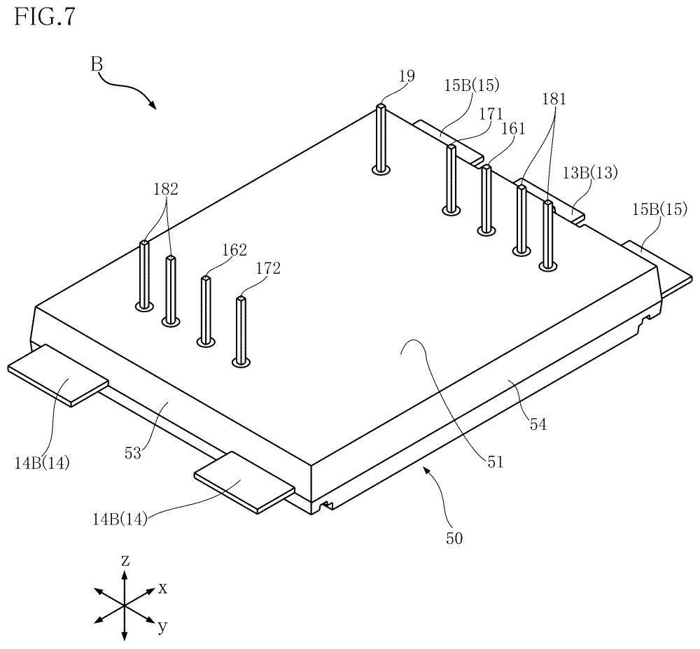

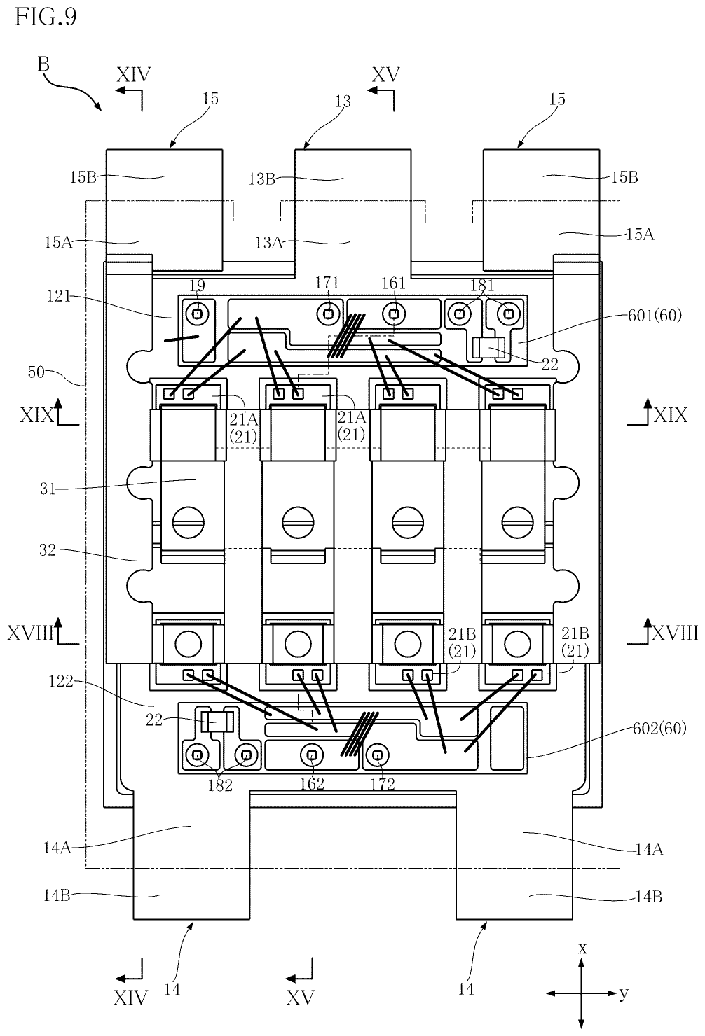

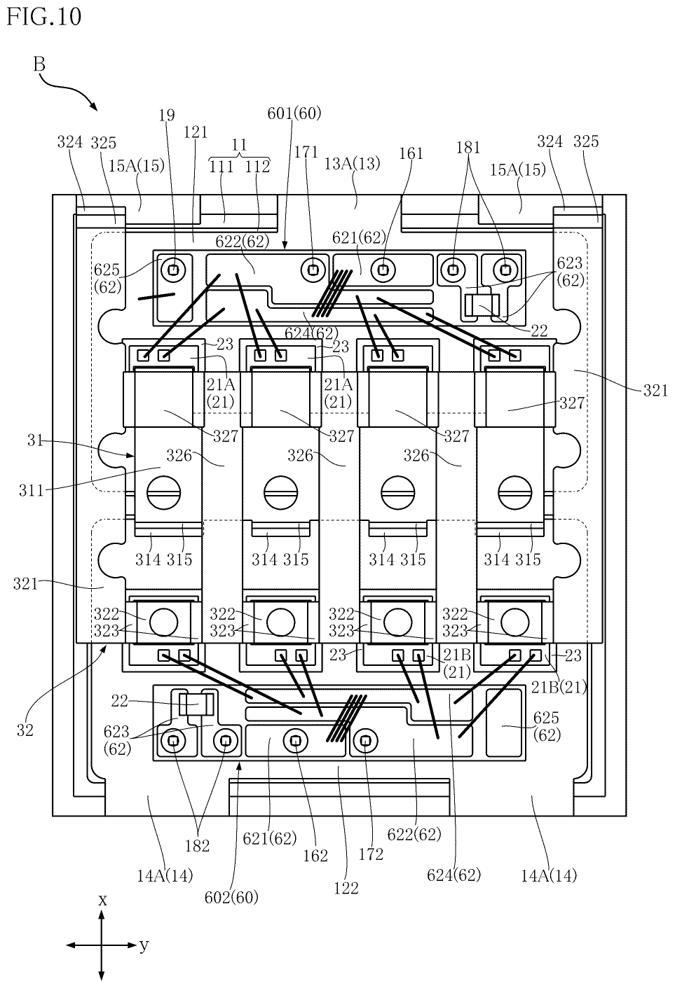

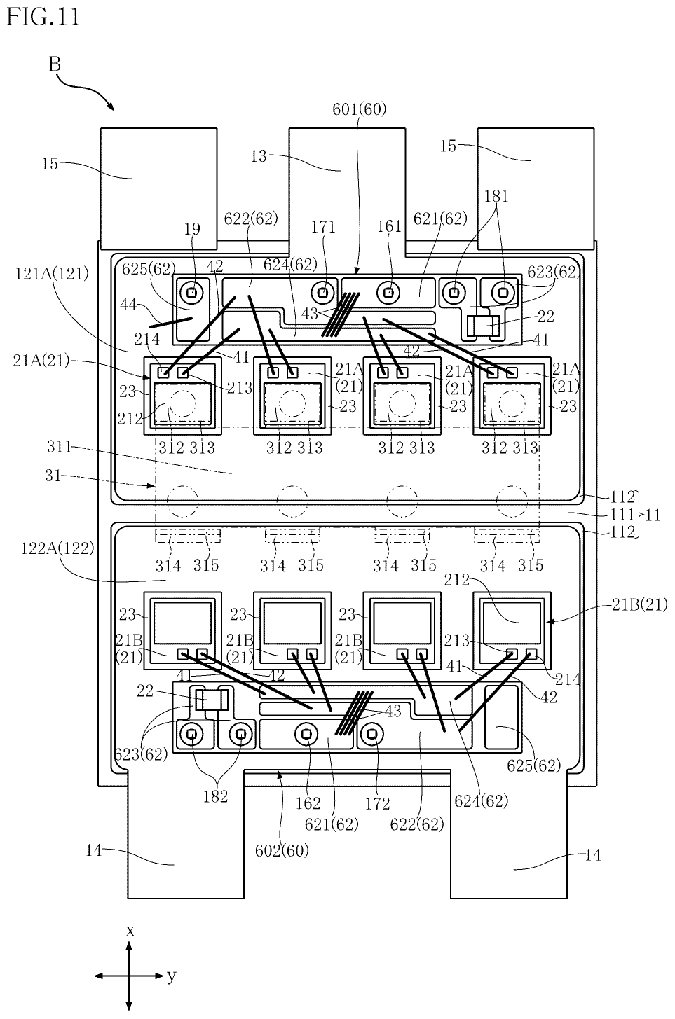

Next, a plurality of semiconductor devices B constituting a semiconductor module C10, described later, will be described based on FIGS. 7 to 19. The plurality of semiconductor devices B are identical with each other. Therefore, description of one of the semiconductor devices B will be given below. The semiconductor device B includes a substrate 11, a first conductive layer 121, a second conductive layer 122, a first input terminal 13, an output terminal 14, a second input terminal 15, a first signal terminal 161, a second signal terminal 162, a plurality of semiconductor elements 21, a first conductive member 31, a second conductive member 32, and a sealing resin 50. The semiconductor device B further includes a third signal terminal 171, a fourth signal terminal 172, a pair of fifth signal terminals 181, a pair of sixth signal terminals 182, a seventh signal terminal 19, a pair of thermistors 22, and a pair of control wirings 60. In FIGS. 9 and 10, the sealing resin 50 is transparent for the convenience of understanding. In FIG. 9, the outline of the sealing resin 50 is shown by imaginary lines (dash-double dot lines). For the convenience of understanding, the first conductive member 31 is transparent while the illustration of the second conductive member 32 and the sealing resin 50 is omitted in FIG. 11.

The semiconductor device B converts the DC power supply voltage applied to the first input terminal 13 and the second input terminal 15 into AC power by the semiconductor elements 21. The converted AC power is inputted through the output terminal 14 to a power supply target, such as a motor.

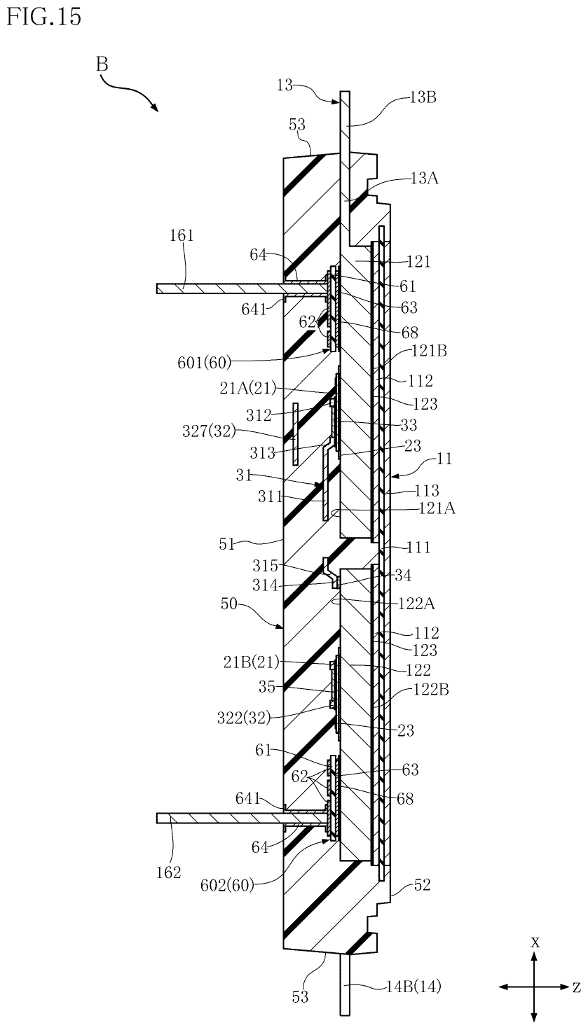

As shown in FIGS. 15 to 17, the substrate 11 is located opposite to the semiconductor elements 21 with the first conductive layer 121 and the second conductive layer 122 interposed therebetween in the first direction z. The substrate 11 supports the first conductive layer 121 and the second conductive layer 122. In the semiconductor device B, the substrate 11 is provided by a DBC (Direct Bonded Copper) substrate. As shown in FIGS. 15 to 17, the substrate 11 includes an insulating layer 111, an intermediate layer 112, and a heat dissipation layer 113. The substrate 11 is covered with the sealing resin 50 except a part of the heat dissipation layer 113.

As shown in FIGS. 15 to 17, the insulating layer 111 includes portions interposed between the intermediate layer 112 and the heat dissipation layer 113 in the first direction z. The insulating layer 111 is made of a material with relatively high thermal conductivity. The insulating layer 111 may be made of ceramic containing aluminum nitride (AlN), for example. The insulating layer 111 may be made of a sheet of insulating resin rather than ceramic. The thickness of the insulating layer 111 is smaller than the thickness of each of the first conductive layer 121 and the second conductive layer 122.

As shown in FIGS. 15 to 17, the intermediate layer 112 is located between the insulating layer 111 and the first and the second conductive layers 121 and 122 in the first direction z. The intermediate layer 112 includes a pair of regions spaced apart from each other in the second direction x. The composition of the intermediate layer 112 includes copper (Cu). As shown in FIG. 11, the intermediate layer 112 is surrounded by the periphery of the insulating layer 111 as viewed along the first direction z.

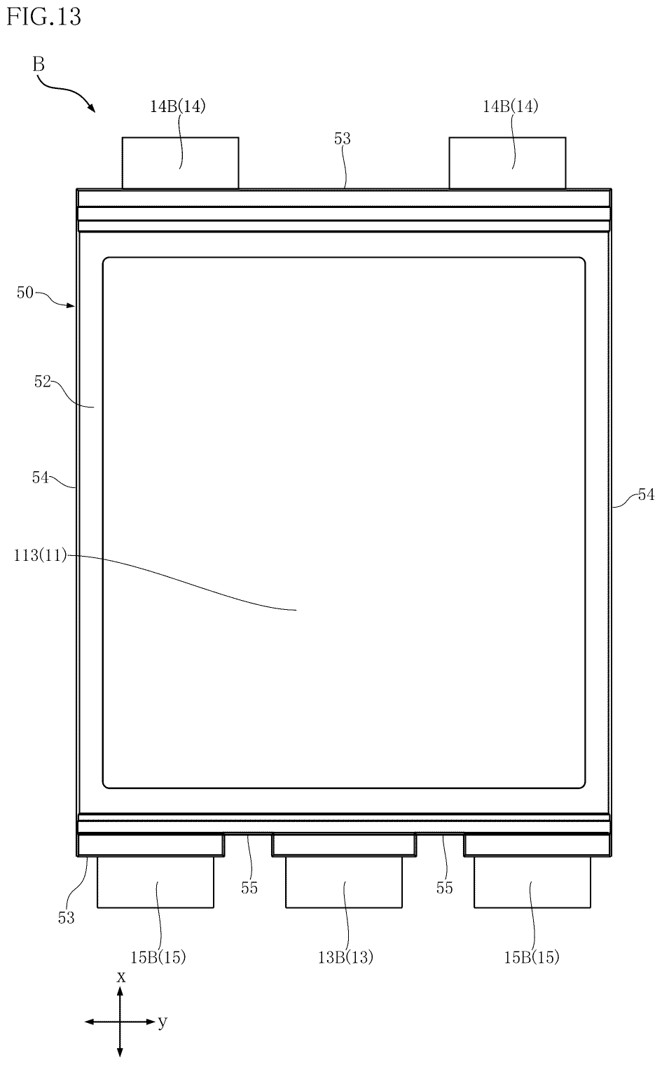

As shown in FIGS. 15 to 17, the heat dissipation layer 113 is located opposite to the intermediate layer 112 with the insulating layer 111 interposed therebetween in the first direction z. As shown in FIG. 13, the heat dissipation layer 113 is exposed from the sealing resin 50. The composition of the heat dissipation layer 113 includes copper. The thickness of the heat dissipation layer 113 is greater than that of the insulating layer 111. The heat dissipation layer 113 is surrounded by the periphery of the insulating layer 111 as viewed along the first direction z.

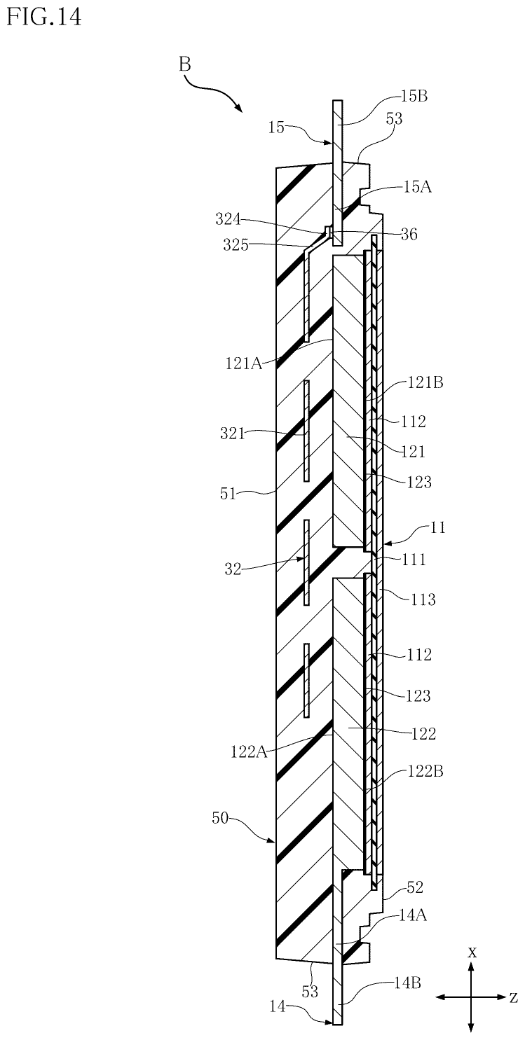

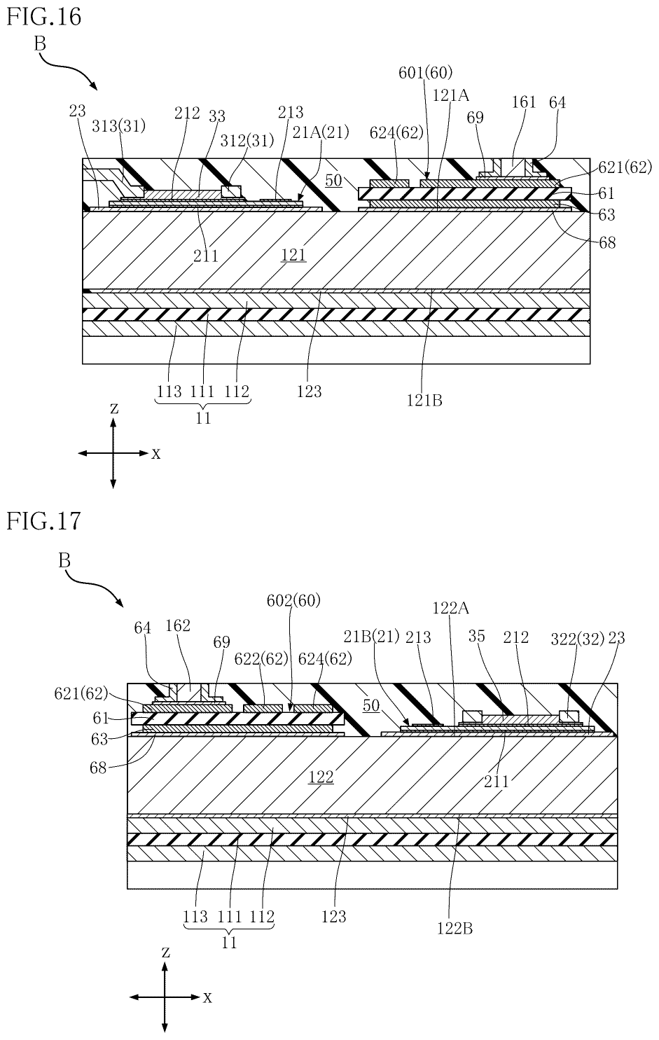

As shown in FIGS. 15 to 17, the first conductive layer 121 and the second conductive layer 122 are bonded to the substrate 11. The composition of the first conductive layer 121 and the second conductive layer 122 includes copper. The first conductive layer 121 and the second conductive layer 122 are spaced apart from each other in the second direction x. As shown in FIGS. 14 and 15, the first conductive layer 121 has a first obverse surface 121A and a first reverse surface 121B facing away from each other in the first direction z. The first obverse surface 121A faces the semiconductor elements 21. As shown in FIG. 16, the first reverse surface 121B is bonded to one of the pair of regions of the intermediate layer 112 via a first adhesive layer 123. The first adhesive layer 123 is, for example, a brazing material containing e.g. silver (Ag) in its composition. As shown in FIGS. 14 and 15, the second conductive layer 122 has a second obverse surface 122A and a second reverse surface 122B facing away from each other in the first direction z. The second obverse surface 122A faces the same side as the first obverse surface 121A in the first direction z. As shown in FIG. 17, the second reverse surface 122B is bonded to the other one of the pair of regions of the intermediate layer 112 via the first adhesive layer 123.

As shown in FIGS. 11 and 15, each of the semiconductor elements 21 is mounted to one of the first conductive layer 121 and the second conductive layer 122. The semiconductor elements 21 are MOSFETs (Metal-Oxide-Semiconductor Field-Effect Transistor), for example. Alternatively, the semiconductor elements 21 may be switching elements, such as IGBTs (Insulated Gate Bipolar Transistor) or diodes. In the semiconductor device B described herein, the semiconductor elements 21 are n-channel MOSFETs of a vertical structure type. The semiconductor elements 21 include a compound semiconductor substrate. The composition of the compound semiconductor substrate includes silicon carbide (SiC).

As shown in FIG. 11, in the semiconductor device B, the plurality of semiconductor elements 21 include a plurality of first elements 21A and a plurality of second elements 21B. The configuration of the second elements 21B is the same as that of the first elements 21A. The first elements 21A are mounted on the first obverse surface 121A of the first conductive layer 121. The first elements 21A are arranged along the third direction y. The second elements 21B are mounted on the second obverse surface 122A of the second conductive layer 122. The second element 21B are arranged along the third direction y.

As shown in FIGS. 11, 16, and 17, each of the semiconductor elements 21 has a first electrode 211, a second electrode 212, a third electrode 213, and a fourth electrode 214.

As shown in FIGS. 16 and 17, the first electrode 211 faces the first conductive layer 121 or the second conductive layer 122. A current corresponding to the electric power before conversion by the semiconductor element 21 flows in the first electrode 211. That is, the first electrode 211 corresponds to the drain electrode of the semiconductor element 21.

As shown in FIGS. 16 and 17, the second electrode 212 is located opposite to first electrode 211 in the first direction z. A current corresponding to the electric power after conversion by the semiconductor element 21 flows in the second electrode 212. That is, the second electrode 212 corresponds to the source electrode of the semiconductor element 21.

As shown in FIGS. 16 and 17, the third electrode 213 is located on the same side as the second electrode 212 in the first direction z. A gate voltage for driving the semiconductor element 21 is applied to the third electrode 213. That is, the third electrode 213 corresponds to the gate electrode of the semiconductor element 21. As shown in FIG. 11, the area of the third electrode 213 is smaller than the area of the second electrode 212 as viewed along the first direction z.

As shown in FIG. 11, the fourth electrode 214 is located on the same side as the second electrode 212 in the first direction z and next to the third electrode 213 in the third direction y. The potential of the fourth electrode 214 is equal to the potential of the second electrode 212.

As shown in FIGS. 16 and 17, conductive bonding layers 23 are interposed between the first conductive layer 121 or the second conductive layer 122 and the first electrodes 211 of the semiconductor elements 21. The conductive bonding layers 23 are solder, for example. Alternatively, the conductive bonding layers 23 may contain sintered metal particles. The first electrode 211 of each of the first elements 21A is conductively bonded to the first obverse surface 121A of the first conductive layer 121 via a conductive bonding layer 23. Thus, the first electrodes 211 of the first elements 21A are electrically connected to the first conductive layer 121. The first electrode 211 of each of the second elements 21B is conductively bonded to the second obverse surface 122A of the second conductive layer 122 via a conductive bonding layer 23. Thus, the first electrodes 211 of the second elements 21B are electrically connected to the second conductive layer 122.

As shown in FIGS. 9 and 15, the first input terminal 13 is located opposite to the second conductive layer 122 with the first conductive layer 121 interposed therebetween in the second direction x and is connected to the first conductive layer 121. Thus, the first input terminal 13 is electrically connected to the first electrodes 211 of the first elements 21A via the first conductive layer 121. The first input terminal 13 is a P terminal (positive electrode) to which a DC power supply voltage to be converted is applied. The first input terminal 13 extends from the first conductive layer 121 in the second direction x. The first input terminal 13 has a covered portion 13A and an exposed portion 13B. As shown in FIG. 15, the covered portion 13A is connected to the first conductive layer 121 and covered with the sealing resin 50. The covered portion 13A is flush with the first obverse surface 121A of the first conductive layer 121. The exposed portion 13B extends from the covered portion 13A in the second direction x and is exposed from the sealing resin 50.

As shown in FIGS. 9 and 14, the output terminal 14 is located opposite to the first conductive layer 121 with the second conductive layer 122 interposed therebetween in the second direction x and is connected to the second conductive layer 122. Thus, the output terminal 14 is electrically connected to the first electrodes 211 of the second elements 21B via the second conductive layer 122. The AC power converted by the semiconductor elements 21 is outputted from the output terminal 14. In the semiconductor device B, the output terminal 14 includes a pair of regions spaced apart from each other in the third direction y. Alternatively, the output terminal 14 may be a single part without a pair of regions. The output terminal 14 has a covered portion 14A and an exposed portion 14B. As shown in FIG. 14, the covered portion 14A is connected to the second conductive layer 122 and covered with the sealing resin 50. The covered portion 14A is flush with the second obverse surface 122A of the second conductive layer 122. The exposed portion 14B extends from the covered portion 14A in the second direction x and is exposed from the sealing resin 50.

As shown in FIGS. 9 and 14, the second input terminal 15 is located on the same side as the first input terminal 13 with respect to the first conductive layer 121 and the second conductive layer 122 in the second direction x and spaced apart from the first conductive layer 121 and the second conductive layer 122. The second input terminal 15 is electrically connected to the second electrodes 212 of the second elements 21B. The second input terminal 15 is an N terminal (negative electrode) to which a DC power supply voltage to be converted is applied. The second input terminal 15 includes a pair of regions spaced apart from each other in the third direction y. The first input terminal 13 is located between the pair of regions in the third direction y. The second input terminal 15 has a covered portion 15A and an exposed portion 15B. As shown in FIG. 14, the covered portion 15A is spaced apart from the first conductive layer 121 and covered with the sealing resin 50. The exposed portion 15B extends from the covered portion 15A in the second direction x and is exposed from the sealing resin 50.

The pair of control wirings 60 form parts of conduction paths between the semiconductor elements 21 and the first signal terminal 161, the second signal terminal 162, the third signal terminal 171, the fourth signal terminal 172, the pair of fifth signal terminals 181, the pair of sixth signal terminals 182. As shown in FIGS. 9 to 11, the pair of control wirings 60 include a first wiring 601 and a second wiring 602. The first wiring 601 is located between the first elements 21A and the first and the second input terminal 13 and 15 in the second direction x. The first wiring 601 is bonded to the first obverse surface 121A of the first conductive layer 121. The first wiring 601 also forms a part of the conduction path between the seventh signal terminal 19 and the first conductive layer 121. The second wiring 602 is located between the second elements 21B and the output terminal 14 in the second direction x. The second wiring 602 is bonded to the second obverse surface 122A of the second conductive layer 122. As shown in FIGS. 16 and 17, each of the pair of control wirings 60 includes an insulating layer 61, a plurality of wiring layers 62, a metal layer 63, and a plurality of sleeves 64. The control wirings 60 are covered with the sealing resin 50 except a part of each sleeve 64.

As shown in FIGS. 16 and 17, the insulating layer 61 includes portions interposed between the wiring layers 62 and the metal layer 63 in the first direction z. The insulating layer 61 is made of ceramic, for example. The insulating layer 61 may be made of a sheet of insulating resin rather than ceramic.

As shown in FIGS. 16 and 17, the wiring layers 62 are located on one side of the insulating layer 61 in the first direction z. The composition of the wiring layers 62 includes copper. As shown in FIG. 11, the wiring layers 62 include a first wiring layer 621, a second wiring layer 622, a pair of third wiring layers 623, a fourth wiring layer 624, and a fifth wiring layer 625. The pair of third wiring layers 623 are arranged next to each other in the third direction y.

As shown in FIGS. 16 and 17, the metal layer 63 is located opposite to the wiring layers 62 with the insulating layer 61 interposed therebetween in the first direction z. The composition of the metal layer 63 includes copper. The metal layer 63 of the first wiring 601 is bonded to the first obverse surface 121A of the first conductive layer 121 with a second adhesive layer 68. The metal layer 63 of the second wiring 602 is bonded to the second obverse surface 122A of the second conductive layer 122 with a second adhesive layer 68. The second adhesive layers 68 may be made of a material having electrical conductivity or a material that does not have electrical conductivity. The second adhesive layers 68 may be solder, for example.

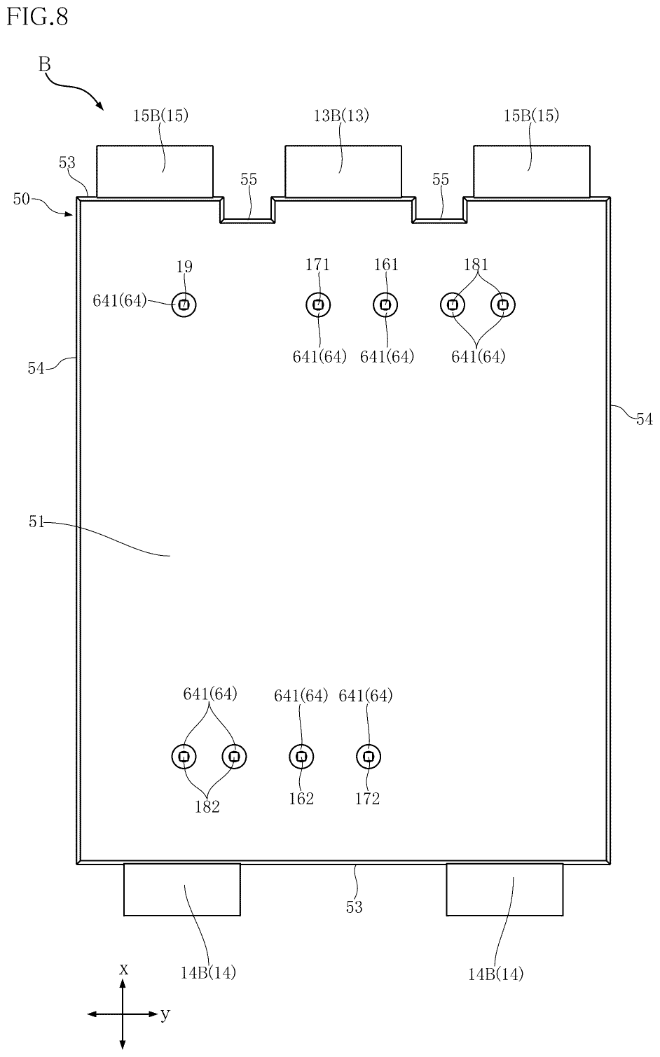

As shown in FIGS. 16 and 17, each of the sleeves 64 is bonded to one of the wiring layers 62 with a third adhesive layer 69. The sleeves 64 are made of an electrically conductive material, such as metal. Each of the sleeves 64 has a cylindrical shape extending along the first direction z. One end of each sleeve 64 is conductively bonded to one of the wiring layers 62. As shown in FIGS. 8 and 15, the other end of each sleeve 64 has an end surface 641 exposed at the top surface 51, described later, of the sealing resin 50. The third adhesive layers 69 have electrical conductivity. The third adhesive layers 69 may be solder, for example.

As shown in FIG. 10, one of the pair of thermistors 22 is conductively bonded to the pair of third wiring layers 623 of the first wiring 601. As shown in FIG. 10, the other one of the pair of thermistors 22 is conductively bonded to the pair of third wiring layers 623 of the second wiring 602. The thermistors 22 are NTC (Negative Temperature Coefficient) thermistors, for example. The NTC thermistors have the characteristic that their resistance gradually decreases as the temperature increases. The thermistors 22 are used as a temperature detection sensor of the semiconductor device B.

The first signal terminal 161, the second signal terminal 162, the third signal terminal 171, the fourth signal terminal 172, the pair of fifth signal terminals 181, the pair of sixth signal terminals 182 and the seventh signal terminal 19 are made of metal pins extending in the first direction z as shown in FIG. 7. These terminals protrude from the top surface 51, described later, of the sealing resin 50. These terminals are individually press-fitted into the sleeves 64 of the control wirings 60. Thus, each of these terminals is supported by one of the sleeves 64 and electrically connected to one of the wiring layers 62.

As shown in FIGS. 11 and 16, the first signal terminal 161 is press-fitted into the sleeve 64 bonded to the first wiring layer 621 of the first wiring 601 of the control wirings 60. Thus, the first signal terminal 161 is supported by the sleeve 64 and electrically connected to the first wiring layer 621 of the first wiring 601. The first signal terminal 161 is also electrically connected to the third electrodes 213 of the first elements 21A. A gate voltage for driving the first elements 21A is applied to the first signal terminal 161.

As shown in FIGS. 11 an 17, the second signal terminal 162 is press-fitted into the sleeve 64 bonded to the first wiring layer 621 of the second wiring 602 of the control wirings 60. Thus, the second signal terminal 162 is supported by the sleeve 64 and electrically connected to the first wiring layer 621 of the second wiring 602. The second signal terminal 162 is also electrically connected to the third electrodes 213 of the second elements 21B. A gate voltage for driving the second element 21B is applied to the second signal terminal 162.

The third signal terminal 171 is located next to the first signal terminal 161 in the third direction y as shown in FIG. 8. As shown in FIG. 11, the third signal terminal 171 is press-fitted into the sleeve 64 bonded to the second wiring layer 622 of the first wiring 601 of the control wirings 60. Thus, the third signal terminal 171 is supported by the sleeve 64 and electrically connected to the second wiring layer 622 of the first wiring 601. The third signal terminal 171 is also electrically connected to the fourth electrodes 214 of the first elements 21A. To the third signal terminal 171 is applied a voltage corresponding to the current that is the highest of the currents flowing in the respective fourth electrodes 214 of the first elements 21A.

The fourth signal terminal 172 is located next to the second signal terminal 162 in the third direction y as shown in FIG. 8. As shown in FIG. 11, the fourth signal terminal 172 is press-fitted into the sleeve 64 bonded to the second wiring layer 622 of the second wiring 602 of the control wirings 60. Thus, the fourth signal terminal 172 is supported by the sleeve 64 and electrically connected to the second wiring layer 622 of the second wiring 602. The fourth signal terminal 172 is also electrically connected to the fourth electrodes 214 of the second elements 21B. To the fourth signal terminal 172 is applied a voltage corresponding to the current that is the highest of the currents flowing in the respective fourth electrodes 214 of the second elements 21B.

The pair of fifth signal terminals 181 are located opposite to the third signal terminal 171 with the first signal terminal 161 interposed therebetween in the third direction y as shown in FIG. 8. The fifth signal terminals 181 are arranged next to each other in the third direction y. As shown in FIG. 11, the pair of fifth signal terminals 181 are individually press-fitted into the pair of sleeves 64 bonded to the pair of third wiring layers 623 of the first wiring 601 of the control wirings 60. Thus, the pair of fifth signal terminals 181 are supported by the pair of sleeves 64 and electrically connected to the pair of third wiring layers 623 of the first wiring 601. The pair of fifth signal terminals 181 are also electrically connected to thermistor 22 conductively bonded to the pair of third wiring layers 623 of the first wiring 601.

The pair of sixth signal terminals 182 are located opposite to the fourth signal terminal 172 with the second signal terminal 162 interposed therebetween in the third direction y as shown in FIG. 8. The sixth signal terminals 182 are arranged next to each other in the third direction y. As shown in FIG. 11, the pair of sixth signal terminals 182 are individually press-fitted into the pair of sleeves 64 bonded to the pair of third wiring layers 623 of the second wiring 602 of the control wirings 60. Thus, the pair of sixth signal terminals 182 are supported by the pair of sleeves 64 and electrically connected to the pair of third wiring layers 623 of the second wiring 602. The pair of sixth signal terminals 182 are also electrically connected to thermistor 22 conductively bonded to the pair of third wiring layers 623 of the second wiring 602.

The seventh signal terminal 19 is located opposite to the first signal terminal 161 with the third signal terminal 171 interposed therebetween in the third direction y as shown in FIG. 8. As shown in FIG. 11, the seventh signal terminal 19 is press-fitted into the sleeve 64 bonded to the fifth wiring layer 625 of the first wiring 601 of the control wirings 60. Thus, the seventh signal terminal 19 is supported by the sleeve 64 and electrically connected to the fifth wiring layer 625 of the first wiring 601. The seventh signal terminal 19 is also electrically connected to the first conductive layer 121. A voltage corresponding to a DC power inputted to the first input terminal 13 and the second input terminal 15 is applied to the seventh signal terminal 19.

As shown in FIG. 11, first wires 41 are conductively bonded to the third electrodes 213 of the first elements 21A and the fourth wiring layer 624 of the first wiring 601. As shown in FIG. 11, third wires 43 are conductively bonded to the fourth wiring layer 624 of the first wiring 601 and the first wiring layer 621 of the first wiring 601. Thus, the first signal terminal 161 is electrically connected to the third electrodes 213 of the first elements 21A. The composition of the first wires 41 and the third wires 43 includes gold (Au). Alternatively, the composition of the first wires 41 and the third wires 43 may include copper or aluminum.

As shown in FIG. 11, first wires 41 are also conductively bonded to the third electrodes 213 of the second elements 21B and the fourth wiring layer 624 of the second wiring 602. As shown in FIG. 11, third wires 43 are also conductively bonded to the fourth wiring layer 624 of the second wiring 602 and the first wiring layer 621 of the second wiring 602. Thus, the second signal terminal 162 is electrically connected to the third electrodes 213 of the second elements 21B.

As shown in FIG. 11, second wires 42 are conductively bonded to the fourth electrodes 214 of the first elements 21A and the second wiring layer 622 of the first wiring 601. Thus, the third signal terminal 171 is electrically connected to the fourth electrodes 214 of the first elements 21A. As shown in FIG. 11, second wires 42 are also conductively bonded to the fourth electrodes 214 of the second elements 21B and the second wiring layer 622 of the second wiring 602. Thus, the fourth signal terminal 172 is electrically connected to the fourth electrodes 214 of the second elements 21B. The composition of the second wires 42 includes gold. Alternatively, the composition of the second wires 42 may include copper or aluminum.

As shown in FIG. 11, a fourth wire 44 is conductively bonded to the fifth wiring layer 625 of the first wiring 601 and the first obverse surface 121A of the first conductive layer 121. The seventh signal terminal 19 is thereby electrically connected to the first conductive layer 121. The composition of the fourth wire 44 includes gold. Alternatively, the composition of the fourth wire 44 may include copper or aluminum.

As shown in FIGS. 11 and 16, the first conductive member 31 is conductively bonded to the second electrodes 212 of the first elements 21A and the second obverse surface 122A of the second conductive layer 122. Thus, the second electrodes 212 of the first elements 21A are electrically connected to the second conductive layer 122. The composition of the first conductive member 31 includes copper. The first conductive member 31 is a metal clip. As shown in FIG. 11, the first conductive member 31 has a main body 311, a plurality of first bond portions 312, a plurality of first connecting portions 313, second bond portions 314, and second connecting portions 315.

The main body 311 is the main part of the first conductive member 31. As shown in FIG. 11, the main body 311 extends in the third direction y. As shown in FIG. 15, the main body 311 bridges the gap between the first conductive layer 121 and the second conductive layer 122.

As shown in FIG. 16, the first bond portions 312 are individually bonded to the second electrodes 212 of the first elements 21A. Each of the first bond portions 312 faces the second electrode 212 of one of the first elements 21A.

As shown in FIG. 11, the first connecting portions 313 are connected to the main body 311 and the first bond portions 312. The first connecting portions 313 are spaced apart from each other in the third direction y. As shown in FIG. 15, as viewed in the third direction y, the first connecting portions 313 are inclined to become farther away from the first obverse surface 121A of the first conductive layer 121 as proceeding from the first bond portions 312 toward the main body 311.

As shown in FIGS. 11 and 15, the second bond portions 314 are bonded to the second obverse surface 122A of the second conductive layer 122. The second bond portions 314 face the second obverse surface 122A. The second bond portions 314 extend in the third direction y. The dimension of the second bond portions 314 in the third direction y is equal to the dimension of the main body 311 in the third direction y.

As shown in FIGS. 11 and 15, the second connecting portions 315 are connected to the main body 311 and the second bond portions 314. As viewed in the third direction y, the second connecting portions 315 are inclined to become farther away from the second obverse surface 122A of the second conductive layer 122 as proceeding from the second bond portions 314 toward the main body 311. The dimension of the second connecting portions 315 in the third direction y is equal to the dimension of the main body 311 in the third direction y.

As shown in FIGS. 15, 16, and 19, the semiconductor device B further includes first conductive bonding layers 33. The first conductive bonding layers 33 are interposed between the second electrodes 212 of the first elements 21A and the first bond portions 312. The first conductive bonding layers 33 conductively bond the second electrodes 212 of the first elements 21A and the first bond portions 312. The first conductive bonding layers 33 may be solder, for example. Alternatively, the first conductive bonding layers 33 may contain sintered metal particles.

As shown in FIG. 15, the semiconductor device B further includes second conductive bonding layers 34. The second conductive bonding layers 34 are interposed between the second obverse surface 122A of the second conductive layer 122 and the second bond portions 314. The second conductive bonding layers 34 conductively bond the second obverse surface 122A and the second bond portions 314. The second conductive bonding layers 34 may be solder, for example. Alternatively, the second conductive bonding layers 34 may contain sintered metal particles.

As shown in FIGS. 10 and 17, the second conductive member 32 is conductively bonded to the second electrodes 212 of the second elements 21B and the covered portion 15A of the second input terminal 15. Thus, the second electrodes 212 of the second elements 21B are electrically connected to the second input terminal 15. The composition of the second conductive member 32 includes copper. The second conductive member 32 is a metal clip. As shown in FIG. 10, the second conductive member 32 has a pair of main bodies 321, a plurality of third bond portions 322, a plurality of third connecting portions 323, a pair of fourth bond portions 324, a pair of fourth connecting portions 325, a pair of intermediate portions 326, and a plurality of beam portions 327.

As shown in FIG. 10, the pair of main bodies 321 are spaced apart from each other in the third direction y. The main bodies 321 extend in the second direction x. As shown in FIG. 14, the main bodies 321 are disposed in parallel to the first obverse surface 121A of the first conductive layer 121 and the second obverse surface 122A of the second conductive layer 122. The main bodies 321 are located farther from the first obverse surface 121A and the second obverse surface 122A than is the main body 311 of the first conductive member 31.

As shown in FIG. 10, the intermediate portions 326 are spaced apart from each other in the third direction y and located between the pair of main bodies 321 in the third direction y. The intermediate portions 326 extend in the second direction x. The dimension of each intermediate portion 326 in the second direction x is smaller than the dimension of each main body 321 in the second direction x.

As shown in FIG. 17, the third bond portions 322 are individually bonded to the second electrodes 212 of the second elements 21B. Each of the third bond portions 322 faces the second electrode 212 of one of the second elements 21B.

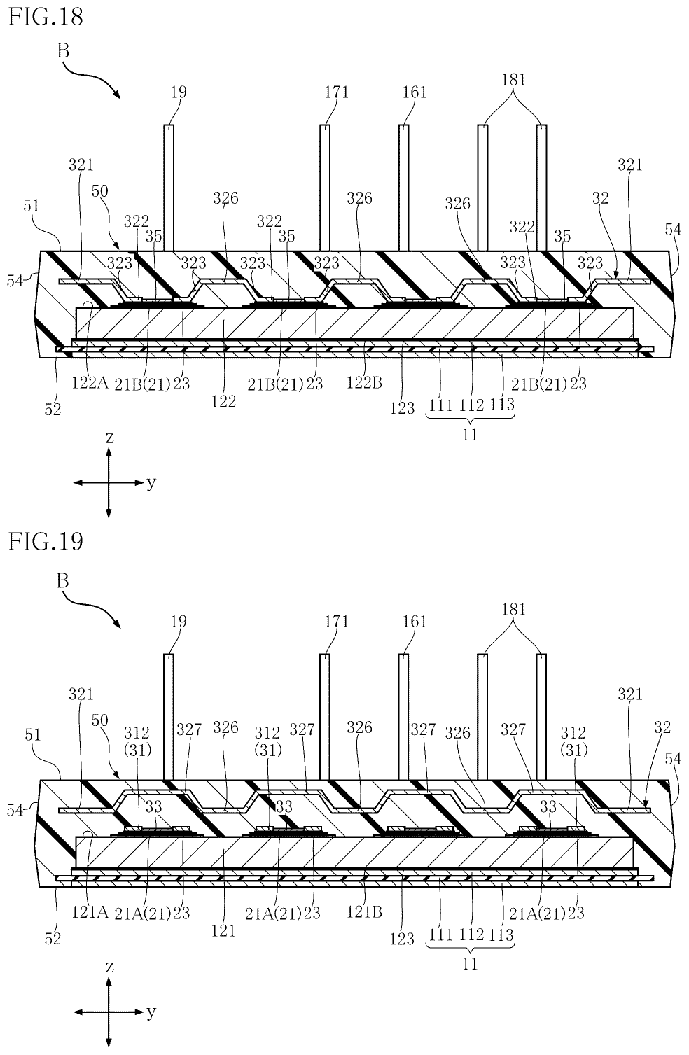

As shown in FIGS. 10 and 18, the third connecting portions 323 are connected to both sides in the third direction y of each third bond portion 322. Each of the third connecting portions 323 is connected to one of the main bodies 321 and intermediate portions 326. As viewed in the second direction x, each of the third connecting portions 323 is inclined to become farther away from the second obverse surface 122A of the second conductive layer 122 as proceeding from one of the third bond portions 322 toward one of the main bodies 321 and intermediate portions 326.

As shown in FIGS. 10 and 14, the pair of fourth bond portions 324 are bonded to the covered portion 15A of the second input terminal 15. The fourth bond portions 324 face the covered portion 15A.

As shown in FIGS. 10 and 14, the pair of fourth connecting portions 325 are connected to the pair of main bodies 321 and the pair of fourth bond portions 324. As viewed along the third direction y, the fourth connecting portions 325 are inclined to become farther away from the first obverse surface 121A of the first conductive layer 121 as proceeding from the fourth bond portions 324 toward the main bodies 321.

As shown in FIGS. 10 and 19, the beam portions 327 are arranged along the third direction y. As viewed along the first direction z, the beam portions 327 include portions individually overlapping with the first bond portions 312 of the first conductive member 31. The beam portions 327 located in the middle area in the third direction y are connected on its both sides in the third direction y to the intermediate portions 326. Each of the remaining two beam portions 327 is connected on one side in the third direction y to one of the main bodies 321 and on the other side in the third direction y to one of the intermediate portions 326. As viewed along the second direction x, the beam portions 327 protrude toward the side that the first obverse surface 121A of the first conductive layer 121 faces in the first direction z.

As shown in FIGS. 15, 17, and 18, the semiconductor device B further includes third conductive bonding layers 35. The third conductive bonding layers 35 are interposed between the second electrodes 212 of the second elements 21B and the third bond portions 322. The third conductive bonding layers 35 conductively bond the second electrodes 212 of the second elements 21B and the third bond portions 322 to each other. The third conductive bonding layers 35 may be solder, for example. Alternatively, the third conductive bonding layers 35 may contain sintered metal particles.

As shown in FIG. 14, the semiconductor device B further includes fourth conductive bonding layers 36. The fourth conductive bonding layers 36 are interposed between the covered portion 15A of the second input terminal 15 and the pair of fourth bond portions 324. The fourth conductive bonding layers 36 conductively bond the covered portion 15A and the fourth bond portions 324 to each other. The fourth conductive bonding layers 36 may be solder, for example. Alternatively, the fourth conductive bonding layers 36 may contain sintered metal particles.

As shown in FIGS. 14, 15, 18, and 19, the sealing resin 50 covers the first conductive layer 121, the second conductive layer 122, the semiconductor elements 21, the first conductive member 31, and the second conductive member 32. The sealing resin 50 further covers a part of each of substrate 11, the first input terminal 13, the output terminal 14 and the second input terminal 15. The sealing resin 50 is electrically insulating. The sealing resin 50 is made of a material containing black epoxy resin, for example. As shown in FIGS. 8 and 12 to 15, the sealing resin 50 has a top surface 51, a bottom surface 52, a pair of first side surfaces 53, a pair of second side surfaces 54, and a pair of recesses 55.

As shown in FIGS. 14 and 15, the top surface 51 faces the same side as the first obverse surface 121A of the first conductive layer 121 in the first direction z. As shown in FIGS. 14 and 15, the bottom surface 52 faces away from the top surface 51 in the first direction z. As shown in FIG. 13, the heat dissipation layer 113 of the substrate 11 is exposed at the bottom surface 52.

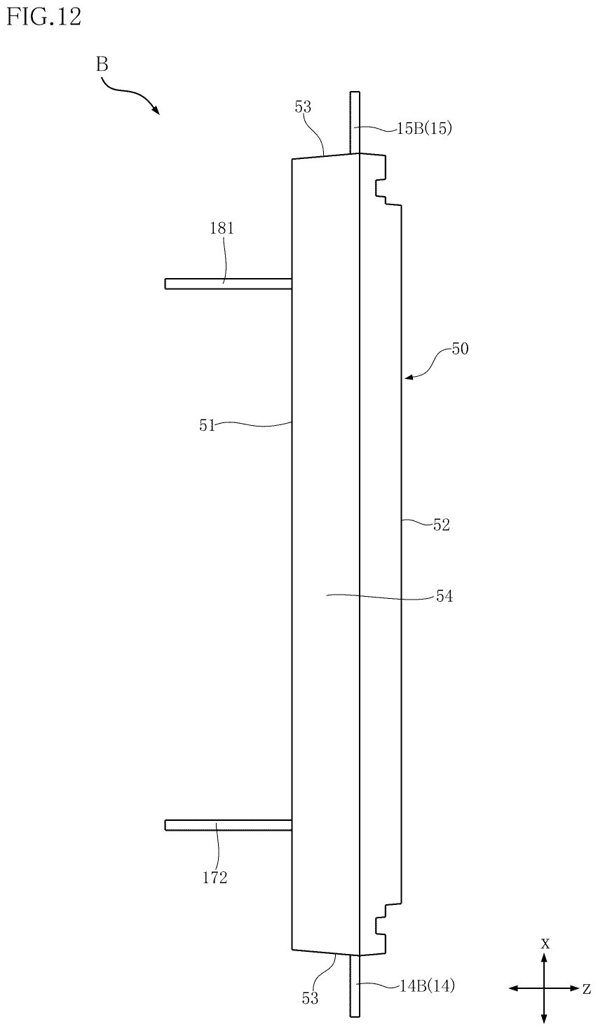

As shown in FIGS. 8 and 12, the pair of first side surfaces 53 are spaced apart from each other in the second direction x. The first side surfaces 53 face in the second direction x and extend in the third direction y. The first side surfaces 53 are connected to the top surface 51. The exposed portion 13B of the first input terminal 13 and the exposed portion 15B of the second input terminal 15 are exposed at one of the first side surfaces 53. The exposed portion 14B of the output terminal 14 is exposed at the other one of the first side surfaces 53.

As shown in FIGS. 8 and 13, the pair of second side surfaces 54 are spaced apart from each other in the third direction y. The second side surfaces 54 face away from each other in the third direction y and extend in the second direction x. The second side surfaces 54 are connected to the top surface 51 and the bottom surface 52.

As shown in FIGS. 8 and 13, the pair of recesses 55 are recessed in the second direction x from the first side surface 53 at which the exposed portion 13B of the first input terminal 13 and the exposed portion 15B of the second input terminal 15 are exposed. The recesses 55 extend from the top surface 51 to the bottom surface 52 in the first direction z. The recesses 55 flank the first input terminal 13 in the third direction y.

### First Embodiment (Semiconductor Module)

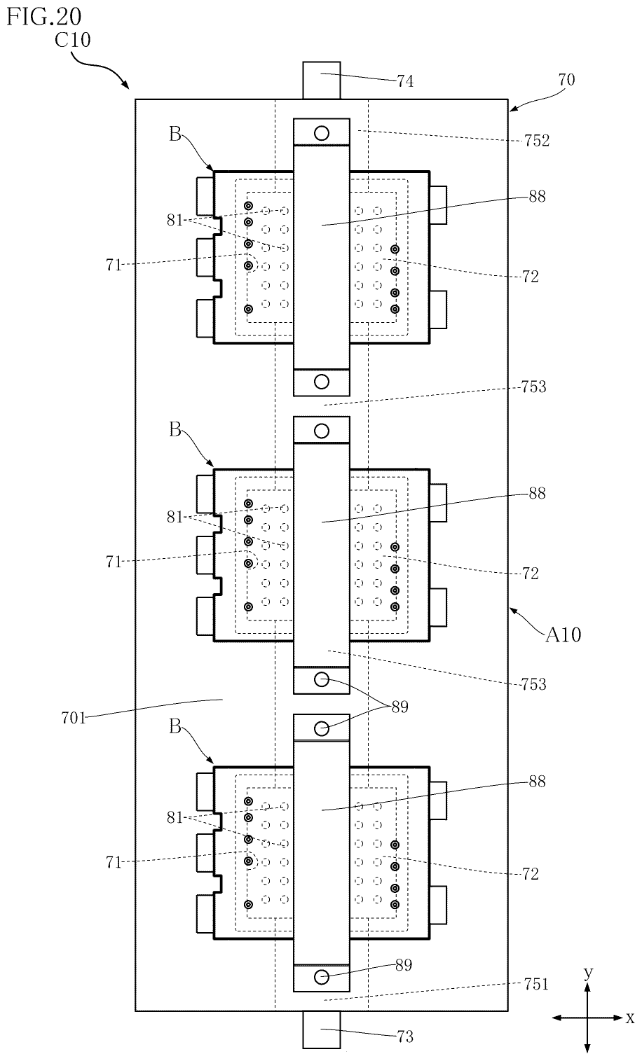

A semiconductor module C10 according to a first embodiment of the present disclosure will be described based on FIGS. 20 to 22. The semiconductor module C10 includes the cooler A10, a plurality of semiconductor devices B, and a plurality of mounting members 88. The semiconductor module C10 constitutes a part of an inverter device for driving, for example, a three-phase AC motor.

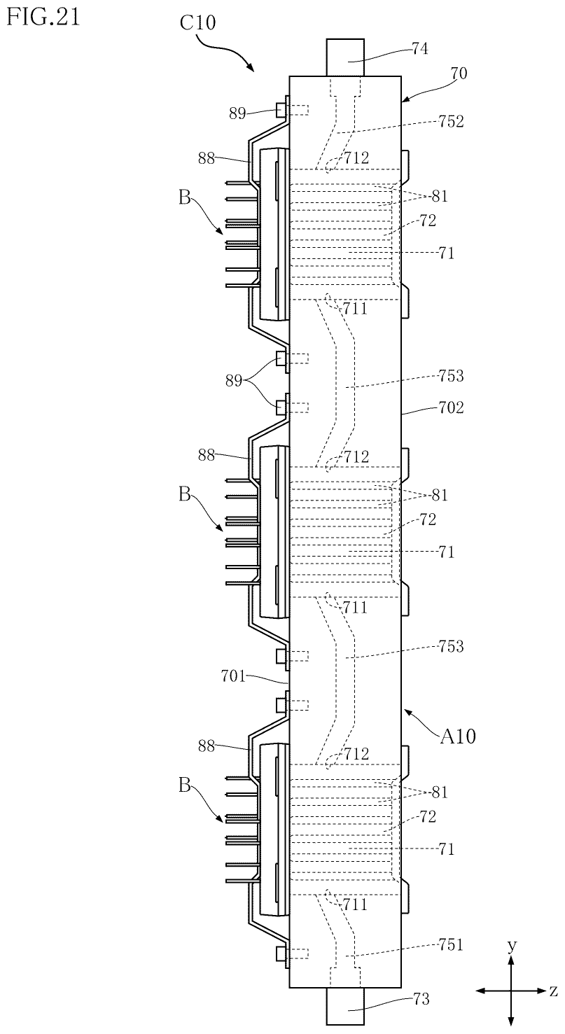

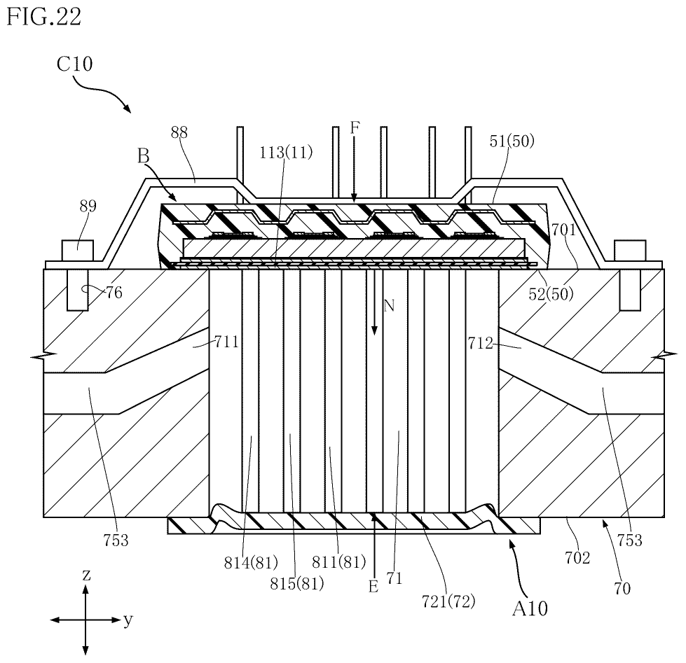

As shown in FIGS. 20 and 21, the semiconductor devices B are disposed on the obverse surface 701 of the housing 70 of the cooler A10. The semiconductor devices B individually cover the recesses 71 of the housing 70 of the cooler A10. More specifically, the heat dissipation layers 113 of the substrates 11 of the semiconductor devices B individually cover the recesses 71 as shown in FIG. 22. Thus, the semiconductor devices B are arranged along the third direction y. The bottom surface 52 of the sealing resin 50 of each semiconductor device B is in contact with the obverse surface 701 of the housing 70. The heat dissipator 81 of the cooler A10 is in contact with the heat dissipation layer 113.

As shown in FIGS. 20 and 21, the mounting members 88 hold the semiconductor devices B on the housing 70 of the cooler A10. The mounting members 88 are made of a material containing a metal. The mounting members 88 are individually held in contact with the top surfaces 51 of the sealing resins 50 of the semiconductor devices B while individually straddling over the top surfaces 51 of the sealing resins 50 of the semiconductor devices B. The mounting members 88 are, for example, leaf springs. Each mounting member 88 is located between the first signal terminal 161 and the second signal terminal 162 of a relevant semiconductor device B in the second direction x. Each mounting member 88 is attached to the housing 70 by inserting two fastening members 89 into two mounting holes 76 provided on opposite sides of the semiconductor device B in the third direction y. The two fastening members 89 are, for example, bolts.

As shown in FIGS. 22, in the semiconductor module C10, a load F acts on the semiconductor device B from the mounting member 88 toward the side on which the heat dissipator 81 of the cooler A10 is located in the first direction z. In response to this, a load N acts on the heat dissipator 81 from the substrate 11 toward the side on which the bottom part 72 of the housing 70 is located in the first direction z. As a result, an elastic force E toward the side on which the heat dissipator 81 is located in the first direction z, which is generated from the flexible portion 721 of the bottom part 72, acts on the heat dissipator 81.

Next, the effects of the cooler A10 and the semiconductor module C10 will be described.

The cooler A10 includes the housing 70 having the recess 71 and the bottom part 72, and the heat dissipator 81 attached to the bottom part 72 and at least partially housed in the recess 71. The recess 71 is open on the first side in the first direction z. The bottom part 72 is located on the second side in the first direction z and defines the recess 71. The bottom part 72 includes the flexible portion 721 that deforms elastically. When a load N toward the second side in the first direction z is applied to the heat dissipator 81, the elastic force E toward the first side in the first direction z, which is generated from the flexible portion 721, acts on the heat dissipator 81. In the semiconductor module C10 shown in FIG. 22 having such a configuration, the heat dissipator 81 is pressed against the semiconductor device B by the elastic force E. Therefore, when the recess 71 is filled with cooling water, the cooling water comes into contact with the heat dissipator 81 and the semiconductor device B, which allows more quick cooling of the semiconductor device B. Moreover, because no gaps are formed on either side of the heat dissipator 81 in the first direction z, the cooling water filling the recess 71 easily contacts the heat dissipator 81 uniformly over the entirety along the first direction z during its flow. Thus, the cooler A10 and the semiconductor module C10 can improve the cooling efficiency with a simpler structure.

The thermal conductivity of the heat dissipator 81 is higher than that of the housing 70. With such a configuration, heat conducts more easily from the semiconductor device B to the heat dissipator 81, and the heat dissipator 81 is more easily cooled by cooling water.

The heat dissipator 81 includes the first member 811 and the second member 812 spaced apart from each other in the second direction x. As viewed in the first direction z, the first member 811 and the second member 812 are surrounded by the obverse surface 701 of the housing 70. With such a configuration, in the semiconductor module C10, the heat dissipator 81 is prevented from being sandwiched between the obverse surface 701 and the semiconductor device B. Moreover, when the load N is applied to the heat dissipator 81 and the elastic force E from the flexible portion 721 of the bottom part 72 acts on the heat dissipator 81, the heat dissipator 81 can move in the first direction z without interfering with the housing 70.

When the flexible portion 721 of the bottom part 72 is in its natural state, each of the first member 811 and the second member 812 protrudes outward from the obverse surface 701 of the housing 70, with the first member 811 protruding by a greater amount than the second member 812. With such a configuration, when the flexible portion 721 has a shape bulging toward the side on which the heat dissipator 81 is located in the first direction z as shown in FIGS. 5 and 6, the flexible portion 721 can be elastically deformed to become flat (or generally flat) as shown in FIG. 22. This allows the first member 811 and the second member 812 to be held in close contact with the semiconductor device B.

The flexible portion 721 of the bottom part 72 is molded in one piece. The first member 811 and the second member 812 are supported on the flexible portion 721. Such a configuration suppresses the loss of the elastic force E acting on the first member 811 and the second member 812.

The first member 811 and the second member 812 include parts protruding outward from the obverse surface 701 of the housing 70. Such a configuration makes it possible to reliably bring the first member 811 and the second member 812 into contact with the semiconductor device B as shown in FIG. 22.

The housing 70 includes the inlet 711 and the outlet 712 connected to the recess 71 and located opposite to each other across the recess 71 in the third direction y. The inlet 711 and the outlet 712 are located between the obverse surface 701 and the reverse surface 702 of the housing 70. Such a configuration allows the cooling water filling in the recess 71 to flow in the third direction y.

The first member 811 overlaps with the inlet 711 and the outlet 712 as viewed in the third direction y. With such a configuration, uneven heat distribution of the cooling water near the first member 811 is prevented.

The distance d1 between the inlet 711 and the obverse surface 701 in the first direction z is shorter than the distance d2 between the inlet 711 and the reverse surface 702 in the first direction z. Also, the distance d3 between the outlet 712 and the obverse surface 701 in the first direction z is shorter than the distance d4 between the outlet 712 and the reverse surface 702 in the first direction z. With such a configuration, in the flow velocity distribution in the first direction z of the cooling water, the flow velocity near the obverse surface 701 is faster than the flow velocity near the reverse surface 702. Because the flow velocity of the cooling water contacting the semiconductor device B is faster, the cooling efficiency of the cooler A10 is further improved.

### Second Embodiment

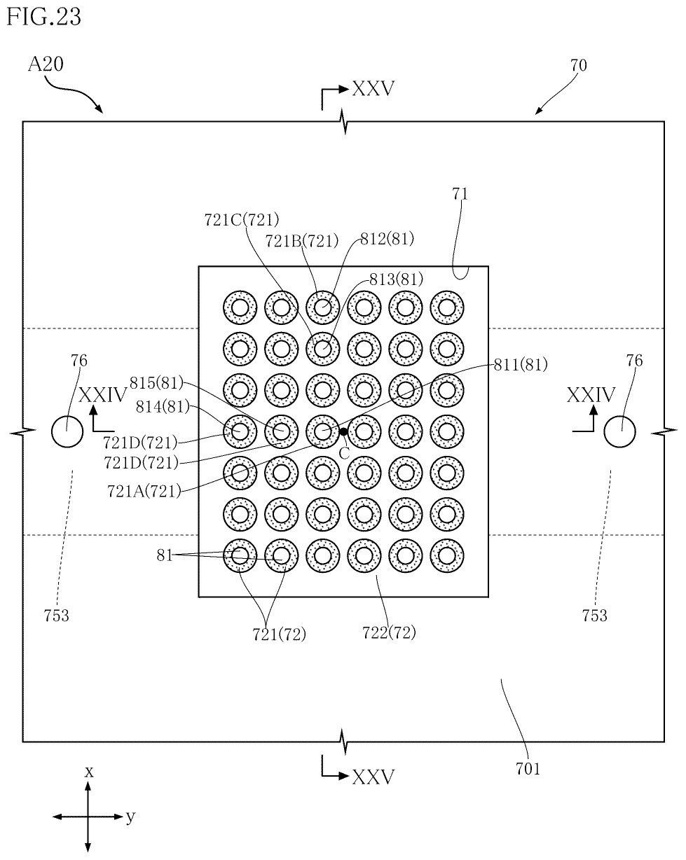

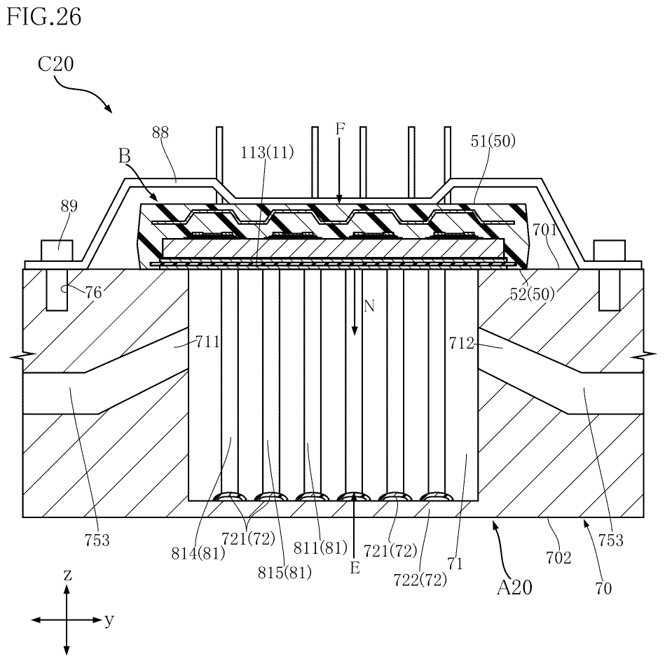

A cooler A20 and a semiconductor module C20 according to a second embodiment of the present disclosure will be described based on FIGS. 23 to 26. In these figures, the elements that are identical or similar to those of the cooler A10 and the semiconductor module C10 described above are denoted by the same reference signs, and the descriptions thereof are omitted. The sectional position of FIG. 26 is the same as the sectional position of FIG. 22 that shows the semiconductor module C10.

The cooler A20 differs from the cooler A10 in the configuration of the bottom part 72 of the housing 70.

As shown in FIGS. 23 to 25, the flexible portion 721 of the bottom part 72 includes a plurality of portions spaced apart from each other. The plurality of portions are arranged in a grid pattern along the second direction x and the third direction y. The bottom part 72 includes a base portion 722. The base portion 722 is formed integrally with other portions of the housing 70. The base portion 722 is flat with respect to the first direction z. The plurality of portions constituting the flexible portion 721 are bonded to the base portion 722.

As shown in FIGS. 23 to 25, the plurality of portions constituting the flexible portion 721 include a first portion 721A, a second portion 721B, a third portion 721C, a fourth portion 721D, and a fifth portion 721E. The first member 811 of the heat dissipator 81 is supported on the first portion 721A. The second member 812 of the heat dissipator 81 is supported on the second portion 721B. The third member 813 of the heat dissipator 81 is supported on the third portion 721C. The fourth member 814 of the heat dissipator 81 is supported on the fourth portion 721D. The fifth member 815 of the heat dissipator 81 is supported on the fifth portion 721E. When the flexible portion 721 is in its natural state, the protruding amount L1 of the first member 811, the protruding amount L2 of the second member 812, the protruding amount L3 of the third member 813, the protruding amount L4 of the fourth member 814 and the protruding amount L5 of fifth member 815 from the obverse surface 701 of the housing 70 to the outside are equal to each other.

As shown in FIG. 26, the semiconductor module C20 includes the cooler A20 instead of the cooler A10. In the semiconductor module C20, a load F acts on the semiconductor device B from the mounting member 88 toward the side on which the heat dissipator 81 of the cooler A10 is located in the first direction z. In response to this, a load N acts on the heat dissipator 81 from the substrate 11 toward the side on which the bottom part 72 of the housing 70 is located in the first direction z. As a result, an elastic force E toward the side on which the heat dissipator 81 is located in the first direction z, which is generated from the flexible portion 721 of the bottom part 72, acts on the heat dissipator 81.

Next, the effects of the cooler A20 and the semiconductor module C20 will be described.

The cooler A20 includes the housing 70 having the recess 71 and the bottom part 72, and the heat dissipator 81 attached to the bottom part 72 and at least partially housed in the recess 71. The recess 71 is open on the first side in the first direction z. The bottom part 72 is located on the second side in the first direction z and defines the recesses 71. The bottom part 72 includes the flexible portion 721 that deforms elastically. When a load N toward the second side in the first direction z is applied to the heat dissipator 81, the elastic force E toward the first side in the first direction z, which is generated from the flexible portion 721, acts on the heat dissipator 81. In the semiconductor module C20 as well, this causes the heat dissipator 81 to be held in contact with the semiconductor device B. Thus, the cooler A20 and the semiconductor module C20 can also improve the cooling efficiency with a simpler structure. The cooler A20 has a configuration in common with the cooler A10, thereby achieving the same effect as the cooler A10.

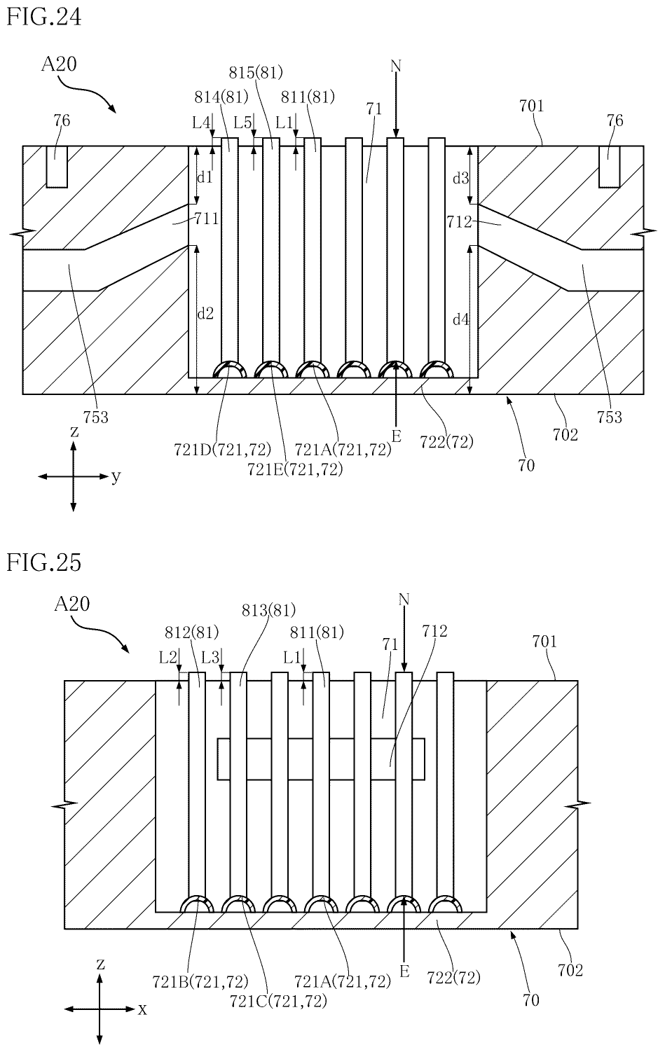

In the cooler A20, the flexible portion 721 of the bottom part 72 includes the first portion 721A and the second portion 721B that are spaced apart from each other. The first member 811 of the heat dissipator 81 is supported on the first portion 721A. The second member 812 of the heat dissipator 81 is supported on the second portion 721B. This configuration allows generation of the elastic force E at each of the first portion 721A and the second portion 721B also in the case where the base portion 722 of the bottom part 72 is flat with respect to the first direction z as shown in FIGS. 24 and 25.

### Third Embodiment

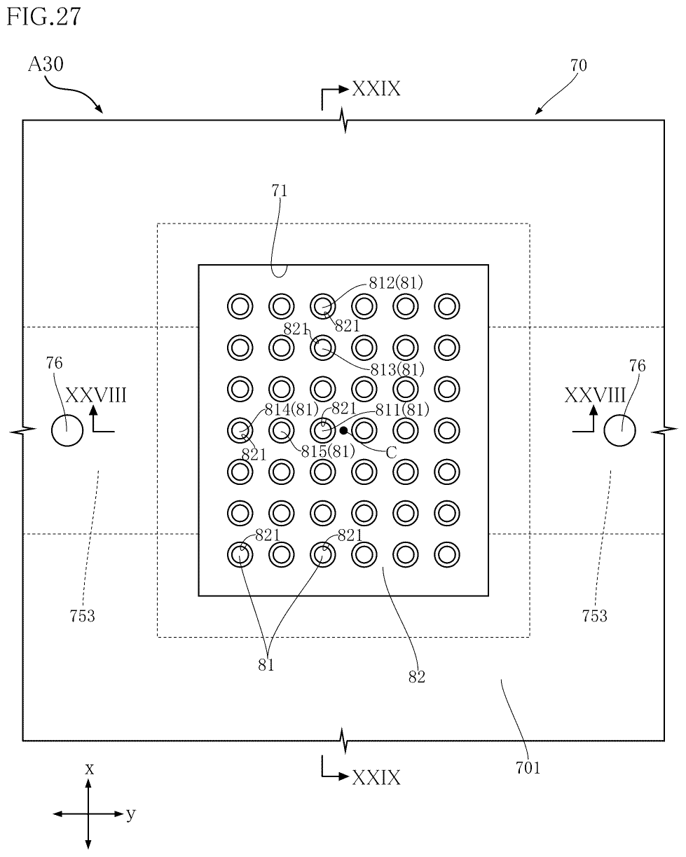

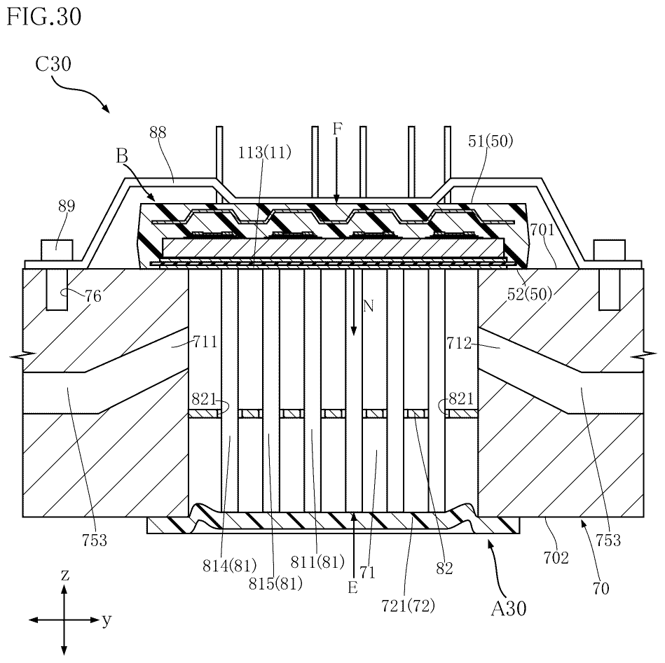

A cooler A30 and a semiconductor module C30 according to a third embodiment of the present disclosure will be described based on FIGS. 27 to 30. In these figures, the elements that are identical or similar to those of the cooler A10 and the semiconductor module C10 described above are denoted by the same reference signs, and the descriptions thereof are omitted. The sectional position of FIG. 30 is the same as the sectional position of FIG. 22 that shows the semiconductor module C10.

Unlike the cooler A10, the cooler A30 further includes a guide member 82.

As shown in FIGS. 27 to 29, the guide member 82 is housed in the recess 71 and bonded to the housing 70. The guide member 82 has a plurality of holes 821 penetrating in the first direction z. The first member 811, the second member 812, the third member 813, the fourth member 814 and the fifth member 815 of the heat dissipator 81 are individually inserted into the holes 821.

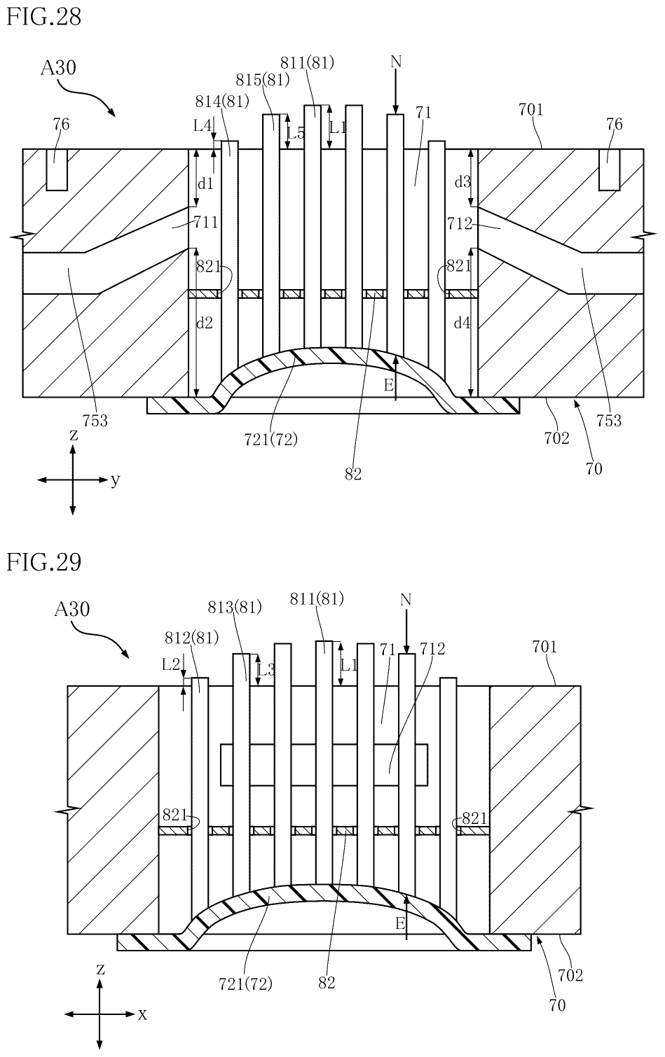

As shown in FIG. 28, the guide member 82 is located between the reverse surface 702 of the housing 70 and the inlet 711 or the outlet 712 in the first direction z.

As shown in FIG. 30, the semiconductor module 320 includes the cooler A30 instead of the cooler A10. In the semiconductor module C30, a load F acts on the semiconductor device B from the mounting member 88 toward the side on which the heat dissipator 81 of the cooler A10 is located in the first direction z. In response to this, a load N acts on the heat dissipator 81 from the substrate 11 toward the side on which the bottom part 72 of the housing 70 is located in the first direction z. As a result, an elastic force E toward the side on which the heat dissipator 81 is located in the first direction z, which is generated from the flexible portion 721 of the bottom part 72, acts on the heat dissipator 81.

Next, the effects of the cooler A30 and the semiconductor module C30 will be described.

The cooler A30 includes the housing 70 having the recess 71 and the bottom part 72, and the heat dissipator 81 attached to the bottom part 72 and at least partially housed in the recess 71. The recess 71 is open on the first side in the first direction z. The bottom part 72 is located on the second side in the first direction z and defines the recesses 71. The bottom part 72 includes the flexible portion 721 that deforms elastically. When a load N toward the second side in the first direction z is applied to the heat dissipator 81, the elastic force E toward the first side in the first direction z, which is generated from the flexible portion 721, acts on the heat dissipator 81. In the semiconductor module C30 as well, this causes the heat dissipator 81 to be held in contact with the semiconductor device B. Thus, the cooler A30 and the semiconductor module C30 can also improve the cooling efficiency with a simpler structure. The cooler A30 has a configuration in common with the cooler A10, thereby achieving the same effect as the cooler A10.

The cooler A30 includes the guide member 82 bonded to the housing 70. The guide member 82 is housed in the recess 71. The guide member 82 has a plurality of holes 821 penetrating in the first direction z. The first member 811 and the second member 812 of the heat dissipator 81 are individually inserted into the holes 821. Thus, movement of the first member 811 and the second member 812 in a direction orthogonal to the first direction z is restricted by the guide member 82. This suppresses deflection of the first member 811 and the second member 812 in a direction orthogonal to the first direction z, so that elastic deformation of the flexible portion 721 of the bottom part 72 due to the load N is effectively achieved.

The guide member 82 is located between the reverse surface 702 of the housing 70 and the inlet 711 or the outlet 712 in the first direction z. This configuration prevents the flow of cooling water from the inlet 711 to the outlet 712 from being hindered in the recess 71.

### Fourth Embodiment

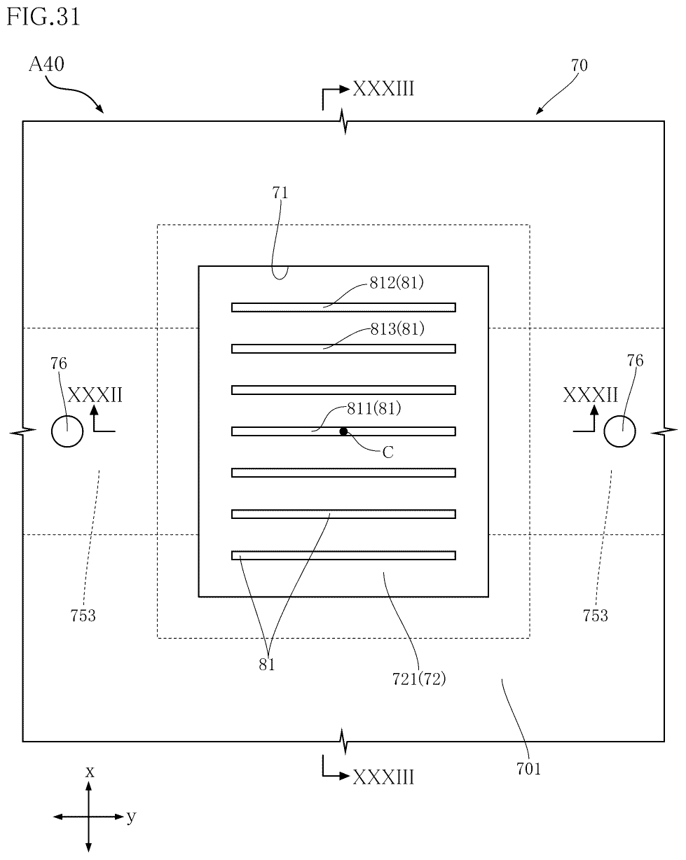

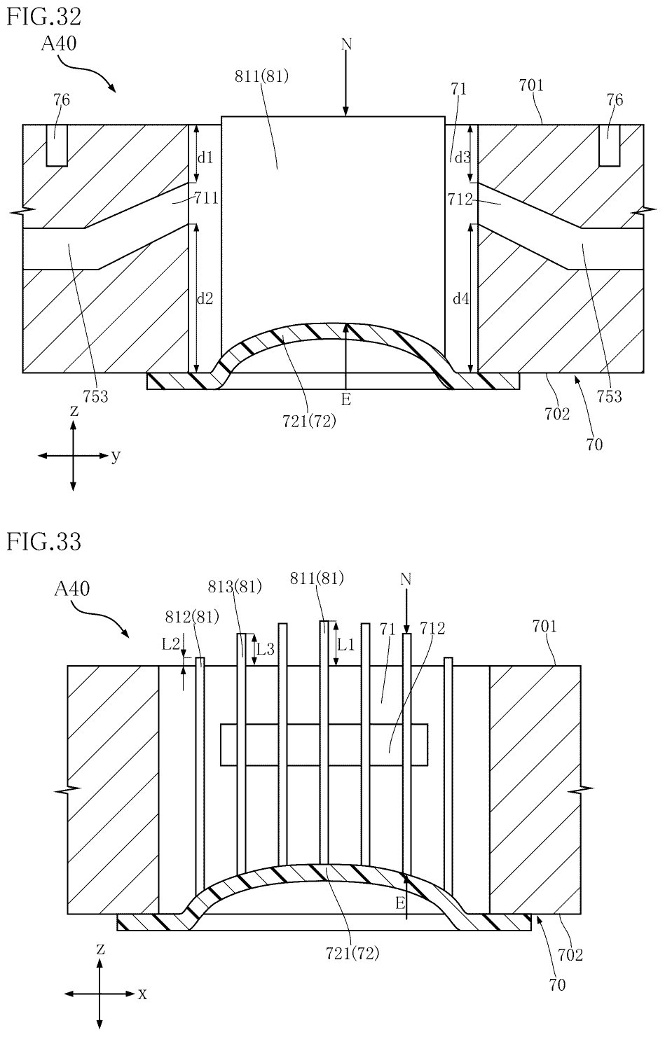

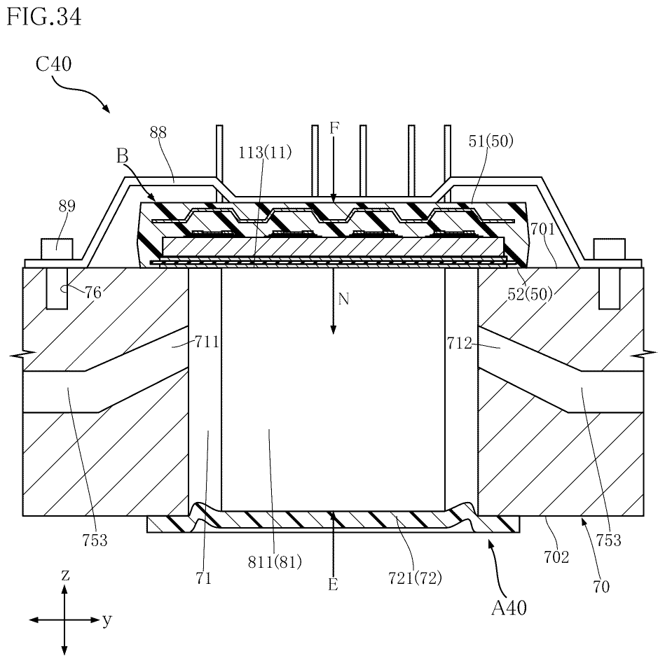

A cooler A40 and a semiconductor module C40 according to a fourth embodiment of the present disclosure will be described based on FIGS. 31 to 34. In these figures, the elements that are identical or similar to those of the cooler A10 and the semiconductor module C10 described above are denoted by the same reference signs, and the descriptions thereof are omitted. The sectional position of FIG. 34 is the same as the sectional position of FIG. 22 that shows the semiconductor module C10.

The cooler A40 differs from the cooler A10 in the configuration of the heat dissipator 81.

As shown in FIGS. 31 to 33, the first member 811, the second member 812 and the third member 813 of the heat dissipator 81 have a plate-like shape extending in the third direction y.

As shown in FIG. 34, the semiconductor module C40 includes the cooler A40 instead of the cooler A10. In the semiconductor module C40, a load F acts on the semiconductor device B from the mounting member 88 toward the side on which the heat dissipator 81 of the cooler A10 is located in the first direction z. In response to this, a load N acts on the heat dissipator 81 from the substrate 11 toward the side on which the bottom part 72 of the housing 70 is located in the first direction z. As a result, an elastic force E toward the side on which the heat dissipator 81 is located in the first direction z, which is generated from the flexible portion 721 of the bottom part 72, acts on the heat dissipator 81.

### Variation:

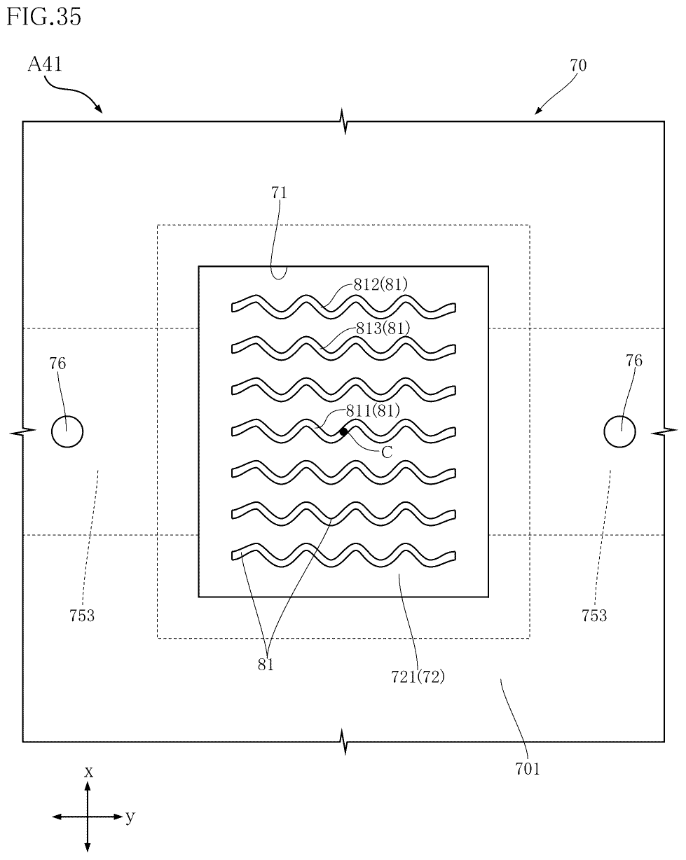

Next, a cooler A41 as a variation of the cooler A40 will be described based on FIG. 35.

The cooler A41 differs from the cooler A40 in the shape of the heat dissipator 81. As shown in FIG. 35, the first member 811, the second member 812, and the third member 813 of the heat dissipator 81 has a wavy shape that meanders in the second direction x.

Next, the effects of the cooler A40 and the semiconductor module C40 will be described.

The cooler A40 includes the housing 70 having the recess 71 and the bottom part 72, and the heat dissipator 81 attached to the bottom part 72 and at least partially housed in the recess 71. The recess 71 is open on the first side in the first direction z. The bottom part 72 is located on the second side in the first direction z and defines the recesses 71. The bottom part 72 includes the flexible portion 721 that deforms elastically. When a load N toward the second side in the first direction z is applied to the heat dissipator 81, the elastic force E toward the first side in the first direction z, which is generated from the flexible portion 721, acts on the heat dissipator 81. In the semiconductor module C40 as well, this causes the heat dissipator 81 to be held in contact with the semiconductor device B. Thus, the cooler A40 and the semiconductor module C40 can also improve the cooling efficiency with a simpler structure. The cooler A40 has a configuration in common with the cooler A10, thereby achieving the same effect as the cooler A10.

In the cooler A40, the first member 811 and the second member 812 of the heat dissipator 81 have a plate-like shape extending in the third direction y. With such a configuration, the flow of cooling water from the inlet 711 to the outlet 712 is not hindered in the recess 71 although the first member 811 and the second member 812 have a plate-like shape.

The present disclosure is not limited to the above-described embodiments. Various modifications in design may be made freely in the specific structure of each part of the semiconductor device according to the present disclosure.

The present disclosure includes embodiments described in the following clauses.

### Clause 1.

A cooler comprising:
a housing including a recess that opens on a first side in a first direction and a bottom part located on a second side in the first direction and defining a part of the recess; and
a heat dissipator attached to the bottom part and at least partially housed in the recess, wherein
the bottom part includes a flexible portion that deforms elastically, and
when a load toward the second side in the first direction is applied to the heat dissipator, an elastic force toward the first side in the first direction, which is generated from the flexible portion, acts on the heat dissipator.

### Clause 2.

The cooler according to clause 1, wherein a thermal conductivity of the heat dissipator is higher than a thermal conductivity of the housing.

### Clause 3.

The cooler according to clause 1 or 2, wherein the bottom part is bonded to the housing.

### Clause 4.

The cooler according to any one of clauses 1 to 3, wherein the heat dissipator includes a first member and a second member spaced apart from each other in a second direction orthogonal to the first direction,
the housing includes an obverse surface facing a side on which the heat dissipator is located with respect to the bottom part in the first direction, the obverse surface surrounding the recess,
the first member and the second member are surrounded by the obverse surface as viewed in the first direction,
the first member is farthest from a center of the recess as viewed in the first direction, and
the second member is closest to the obverse surface.

### Clause 5.

The cooler according to clause 4, wherein when the flexible portion is in a natural state, each of the first member and the second member protrudes outward from the obverse surface, with the first member protruding by a greater amount than the second member.

### Clause 6.

The cooler according to clause 5, wherein the heat dissipator further includes a third member located between the first member and the second member in the second direction, and
when the flexible portion is in a natural state, each of the first member, the second member, and the third member protrudes outward from the obverse surface, with the first member protruding by a greater amount than the third member while the third member protruding by a greater amount than the second member.

### Clause 7.

The cooler according to any one of clauses 4 to 6, wherein the flexible portion is molded in one piece, and
the first member and the second member are supported on the flexible portion.

### Clause 8.

The cooler according to clause 4, wherein the flexible portion includes a first portion and a second portion spaced apart from each other,
the first member is supported on the first portion, and
the second member is supported on the second portion.

### Clause 9.

The cooler according to any one of clauses 4 to 8, wherein each of the first member and the second member includes a part protruding outward from the obverse surface.

### Clause 10.

The cooler according to any one of clauses 4 to 9, wherein the housing includes a reverse surface facing away from the obverse surface in the first direction,
the recess is provided with an inlet and an outlet,
the inlet and the outlet are located opposite to each other across the recess in a third direction orthogonal to the first direction and the second direction, and
the inlet and the outlet are located between the obverse surface and the reverse surface.

### Clause 11.

The cooler according to clause 10, wherein the first member and the second member have a plate-like shape extending in the third direction.

### Clause 12.

The cooler according to clause 10 or 11, wherein the first member overlaps with the inlet and the outlet as viewed in the third direction.

### Clause 13.

The cooler according to any one of clauses 10 to 12, wherein a distance between the inlet and the obverse surface in the first direction is shorter than a distance between the inlet and the reverse surface in the first direction, and
a distance between the outlet and the obverse surface in the first direction is shorter than a distance between the outlet and the reverse surface in the first direction.

### Clause 14.

The cooler according to any one of clauses 10 to 13, further comprising a guide member housed in the recess and bonded to the housing, wherein
the guide member includes a plurality of holes penetrating in the first direction, and
the first member and the second member are individually inserted into the plurality of holes.

### Clause 15.

The cooler according to clause 14, wherein the guide member is located between the reverse surface and the inlet or the outlet in the first direction.

### Clause 16.

A semiconductor module comprising:
the cooler as set forth in any one of clauses 1 to 15;
a semiconductor device disposed on the cooler; and
a mounting member that holds the semiconductor device on the cooler, wherein
the semiconductor device covers the recess,
the heat dissipator is held in contact with the semiconductor device, and
a load toward a side on which the heat dissipator is located in the first direction acts from the mounting member on the semiconductor device.

### Clause 17.

The semiconductor module according to clause 16, wherein the semiconductor device includes a substrate, a conductive layer supported on the substrate, a semiconductor element located opposite to the substrate with respect to the conductive layer and bonded to the conductive layer, and a sealing resin covering the conductive layer and the semiconductor element,
the substrate is exposed outside from the sealing resin,
the mounting member is held in contact with the sealing resin, and
the heat dissipator is held in contact with the substrate.

### REFERENCE NUMERALS

A10, A20, A30, A40: Cooler
B: Semiconductor device
C10, C20, C30, C40: Semiconductor module
11: Substrate
111: Insulating layer
112: Intermediate layer
113: Heat dissipation layer
121: First conductive layer
121A: First obverse surface
121B: First reverse surface
122: Second conductive member
122A: Second obverse surface
122B: Second reverse surface
123: First adhesive layer
13: First input terminal
13A: Covered portion
13B: Exposed portion
14: Output terminal
14A: Covered portion
14B: Exposed portion
15: Second input terminal
15A: Covered portion
15B: Exposed portion
161: First signal terminal
161A: Base portion
161B: Bulging portion
161C: Seat portion
162: Second signal terminal
171: Third signal terminal
172: Fourth signal terminal
181: Fifth signal terminal
182: Sixth signal terminal
19: Seventh signal terminal
21: Semiconductor element
21A: First element
21B: Second element
211: First electrode
212: Second electrode
213: Third electrode
214: Fourth electrode
22: Thermistor
23: Conductive bonding layer
31: First conductive member
311: Main body
312: First bond portion
313: First connecting portion
314: Second bond portion
315: Second connecting portion
32: Second conductive member
321: Main body
322: Third bond portion
323: Third connecting portion
324: Fourth bond portion
325: Fourth connecting portion
326: Intermediate portion
327: Beam portion
33: First conductive bonding layer
34: Second conductive bonding layer
35: Third conductive bonding layer
36: Fourth conductive bonding layer
41: First wire
42: Second wire
43: Third wire
44: Fourth wire
50: Sealing resin
51: Top surface
52: Bottom surface
53: First side surface
54: Second side surface
55: Recess
60: Control wiring
601: First wiring
602: Second wiring
61: Insulating layer
62: Wiring layer
621: First wiring layer
622: Second wiring layer
623: Third wiring layer
624: Fourth wiring layer
625: Fifth wiring layer
63: Metal layer
64: Sleeve
641: End surface
68: Second adhesive layer
69: Third adhesive layer
70: Housing
701: Obverse surface
702: Reverse surface
71: Recess
711: Inlet
712: Outlet
72: Bottom part
721: Flexible portion
721A: First portion
721B: Second portion
721C: Third portion
721D: Fourth portion
721E: Fifth portion
722: Base portion
73: Inlet part
74: Outlet part
751: First flow path
752: Second flow path
753: Intermediate flow path
76: Mounting hole
81: Heat dissipator
811: First member
812: Second member
813: Third member
814: Fourth member
815: Fifth member
82: Guide member
821: Hole
88: Mounting member
89: Fastening member
z: First direction
x: Second direction
y: Third direction

1. A cooler comprising:
a housing including a recess that opens on a first side in a first direction and a bottom part located on a second side in the first direction and defining a part of the recess; and
a heat dissipator attached to the bottom part and at least partially housed in the recess, wherein
the bottom part includes a flexible portion that deforms elastically, and
when a load toward the second side in the first direction is applied to the heat dissipator, an elastic force toward the first side in the first direction, which is generated from the flexible portion, acts on the heat dissipator.

2. The cooler according to claim 1, wherein a thermal conductivity of the heat dissipator is higher than a thermal conductivity of the housing.

3. The cooler according to claim 1, wherein the bottom part is bonded to the housing.

4. The cooler according to claim 1, wherein the heat dissipator includes a first member and a second member spaced apart from each other in a second direction orthogonal to the first direction,
the housing includes an obverse surface facing a side on which the heat dissipator is located with respect to the bottom part in the first direction, the obverse surface surrounding the recess,
the first member and the second member are surrounded by the obverse surface as viewed in the first direction,
the first member is farthest from a center of the recess as viewed in the first direction, and
the second member is closest to the obverse surface.

5. The cooler according to claim 4, wherein when the flexible portion is in a natural state, each of the first member and the second member protrudes outward from the obverse surface, with the first member protruding by a greater amount than the second member.

6. The cooler according to claim 5, wherein the heat dissipator further includes a third member located between the first member and the second member in the second direction, and
when the flexible portion is in a natural state, each of the first member, the second member, and the third member protrudes outward from the obverse surface, with the first member protruding by a greater amount than the third member while the third member protruding by a greater amount than the second member.

7. The cooler according to claim 4, wherein the flexible portion is molded in one piece, and
the first member and the second member are supported on the flexible portion.

8. The cooler according to claim 4, wherein the flexible portion includes a first portion and a second portion spaced apart from each other,
the first member is supported on the first portion, and
the second member is supported on the second portion.

9. The cooler according to claim 4, wherein each of the first member and the second member includes a part protruding outward from the obverse surface.

10. The cooler according to claim 4, wherein the housing includes a reverse surface facing away from the obverse surface in the first direction,
the recess is provided with an inlet and an outlet,
the inlet and the outlet are located opposite to each other across the recess in a third direction orthogonal to the first direction and the second direction, and
the inlet and the outlet are located between the obverse surface and the reverse surface.

11. The cooler according to claim 10, wherein the first member and the second member have a plate-like shape extending in the third direction.

12. The cooler according to claim 10, wherein the first member overlaps with the inlet and the outlet as viewed in the third direction.

13. The cooler according to claim 10, wherein a distance between the inlet and the obverse surface in the first direction is shorter than a distance between the inlet and the reverse surface in the first direction, and
a distance between the outlet and the obverse surface in the first direction is shorter than a distance between the outlet and the reverse surface in the first direction.

14. The cooler according to claim 10, further comprising a guide member housed in the recess and bonded to the housing, wherein
the guide member includes a plurality of holes penetrating in the first direction, and
the first member and the second member are individually inserted into the plurality of holes.

15. The cooler according to claim 14, wherein the guide member is located between the reverse surface and the inlet or the outlet in the first direction.

16. A semiconductor module comprising:
the cooler as set forth in claim 1;
a semiconductor device disposed on the cooler; and
a mounting member that holds the semiconductor device on the cooler, wherein
the semiconductor device covers the recess,
the heat dissipator is held in contact with the semiconductor device, and
a load toward a side on which the heat dissipator is located in the first direction acts from the mounting member on the semiconductor device.

17. The semiconductor module according to claim 16, wherein the semiconductor device includes a substrate, a conductive layer supported on the substrate, a semiconductor element located opposite to the substrate with respect to the conductive layer and bonded to the conductive layer, and a sealing resin covering the conductive layer and the semiconductor element,
the substrate is exposed outside from the sealing resin,
the mounting member is held in contact with the sealing resin, and
the heat dissipator is held in contact with the substrate.
